(19) United States
(12) Patent Application Publication
(10) Pub. No.: US 2026/0289700 A1
(43) Pub. Date: Sep. 24, 2026

(54) ARTIFICIAL INTELLIGENCE POWERED PRECONSTRUCTION PLATFORM

(71) Applicant: Rezio LLC, Phoenix, AZ (US)

(72) Inventors: Mike Adams, Phoenix, AZ (US); Randall Marks, Phoenix, AZ (US); Kristen Adams, Phoenix, AZ (US)

(73) Assignee: Rezio LLC, Phoenix, AZ (US)

(21) Appl. No.: 19/564,912

(22) Filed: Mar. 12, 2026

Related U.S. Application Data
(60) Provisional application No. 63/773,760, filed on Mar. 18, 2025.

(51) Int. Cl. G06Q 50/163; G06F 30/12

(52) U.S. Cl. CPC G06Q 50/163; G06F 30/12

(57) ABSTRACT

An all-in-one artificial intelligence (AI) powered preconstruction platform to provide automated discovery including property analysis and project scoping, rendering, designing, engineering, procurement, permitting, and/or support services throughout the preconstruction process. The platform provides automated feasibility analysis, as-built documentation, new design plans or design modifications to existing as-built plans, engineering calculations and validation, material procurement, permit submissions, and/or ongoing construction support post-permit approval.

### CROSS REFERENCES TO RELATED APPLICATIONS

This application claims priority to U.S. Application No. 63/773,760, filed Mar. 18, 2025, which is incorporated herein by reference in its entirety.

### BACKGROUND OF THE INVENTION

### 1. Field of the Invention

The present invention relates to construction planning and more specifically to preconstruction planning and management utilizing artificial intelligence (AI).

### 2. Description of the Prior Art

It is generally known in the prior art to provide general construction management technology.

Prior art patent documents include the following:

US Patent Publication No. 2025/0005529 for dynamic logic generator for incongruous information in construction project planning applications by inventors Bynum, et al., filed Jun. 30, 2023, and published Jan. 2, 2025, is directed to a computing platform is configured to: (i) generate a logical flowchart for a construction project task, the logical flowchart based on at least one incongruous rule and at least one incongruous data set; (ii) generate a text-based graphical user interface (GUI) prompt based on the logical flowchart; (iii) cause the text-based GUI prompt to be presented via one or more of the first client station, the second client station, or combinations thereof; (iv) receive, from a client station, an indication of user input to the text-based GUI prompt; and (v) cause the text-based GUI prompt to present output information, via the first client station, based on the logical flowchart and the user input.

US Patent Publication No. 2025/0005531 for Multi-modal artificial intelligence platform for building construction by inventors Connaughton, et al., filed Jun. 28, 2024, and published Jan. 2, 2025, is directed to methods, systems, and apparatus, including computer programs encoded on computer-storage media, for a multi-modal artificial intelligence platform for building construction. The multi-model artificial intelligence platform includes various engines that perform various computer-implemented methods. The various engines include a site selector artificial intelligence (AI) engine, a geospatial database, a site compliance analyzer AI engine, a masterplan generator AI engine, a compliance analyzer AI engine, an aesthetic generator AI engine, a schematic generator AI engine, a construction plan generator AI engine, a project timeline generator AI engine, a compliance application generator AI engine, and a financial model generator AI engine.

Respective AI engines collaboratively cooperate for end-to-end AI-driven building construction design and development.

U.S. Pat. No. 9,406,039 for Systems and methods for collaborative construction planning by inventors Reed, et al., filed Mar. 12, 2014, and issued Aug. 2, 2016, is directed to systems and methods for collaborative construction planning. An example method includes establishing a milestone or completion event for a construction project plan, assembling the construction project plan by defining activities for the milestone or completion event. Each of the activities is associated with a team member which accomplishes a given activity, and arranging the activities in reverse chronological order starting with the milestone or completion event, according to an order of dependency of execution of activities. The method also includes displaying the construction project plan in such a way that the activities are illustrated to show the order of dependency between activities.

US Patent Publication No. 2007/0061181 for System and method for construction planning by inventors Bowden, et al., filed Sep. 12, 2005, and published Mar. 15, 2007, is directed to systems and methods for construction planning, including the take-off process, estimating, specification and merchandising of resources used in construction projects. In one embodiment, an object class for each of a plurality of resources is created. Resources are the materials, equipment and labor that are required to complete a construction project. Each object class represents an absolute property of each resource. One or more specification classes for each resource are also created, wherein the specification classes represent discretionary properties of each resource. Each specification class is associated with a corresponding object class for each resource. A take-off of the plurality of resources is estimated based on the object class of each resource in combination with a selected specification class associated with an object class for each resource. Alternative take-offs of the plurality of resources may be estimated based on alternate specification classes in combination with the object class of each resource.

U.S. Pat. No. 9,152,934 for Arrangements for administering and managing a construction project by inventors Carlson, et al., filed Nov. 22, 2011, and issued Oct. 6, 2015, is directed to a construction project administration system and method that queries an administrator as to ownership, construction specifications, bidding parameters etc. for a proposed construction project using active first, second and third level questions and accepts and stores replies to the active questions. The stored replies can be compared to predetermined answers, and questions that become irrelevant based on the answers can be deactivated and taken off a list of questions to be asked. After a sufficient amount of questions are answered, the system can auto-configure a process for online construction management. For example a website can be set up that can be used by all parties to the project to automate communications, the exchange of data, status updates etc. including the submission of bids, acceptance of bids, and the award of contracts and many more paperless construction management features.

U.S. Pat. No. 9,430,749 for Architectural planning system and process therefor by inventors Nagy, et al., filed May 16, 2013, and issued Aug. 30, 2016, is directed to an architectural planning system, that includes software and the process thereof, which actively tracks the relationship of organizational groups as well as the required connections therebetween, which information can be actively taken into account during an architectural planning phase. Generally, this provides an improved software tool and process for planning the physical locations of organizational groups within the building space. Further, changes in organizational needs can be readily modified and adapted through direct and dynamic collaboration between these parties.

U.S. Pat. No. 10,816,941 for Energy efficiency of a building at the planning stage by inventors Frey, et al., filed May 30, 2018, and issued Oct. 27, 2020, is directed to methods and systems for improving the energy efficiency of a building at the planning stage, such as: building a basic digital model of the building using a computer, defining a plurality of different function-related room categories; assigning existing technical building automation functions, previously stored in a memory coupled to the computer, to the different room categories; arranging rooms by assigning the defined categories to the model on the basis of an occupancy plan; coupling the rooms to supply lines of a automation system based on the assigned functions; determining an energy efficiency of the virtual building; and selecting suitable technical system modules from available modules based on the determined energy efficiency.

US Patent Publication No. 2024/0394422 for System and method for generating intelligent virtual representations of architecture, engineering, and construction (AEC) constructs by inventor Kumar, filed May 23, 2024, and published Nov. 28, 2024, is directed to a system for generating virtual representations of architecture, engineering, and construction (AEC) smart constructs. The system includes a controller that determines user intent based on an analysis of a user input and further determines project objective constraints based on an evaluation of project objectives. Knowledge units are computed based on a plurality of nodes and a plurality of interdependencies of a computational graph. The plurality of nodes corresponds to the user intent, and the plurality of interdependencies is established based on the project objectives. Based on the knowledge units, computational simulations for the user intent are performed. Further, virtual representations of the AEC smart constructs in a digital environment are generated based on the computational simulations. The computational simulations meet a defined criteria associated with the project objectives.

U.S. Pat. No. 11,200,522 for System and method linking building information modeling and enterprise resource planning by inventors Harris, et al., filed Feb. 27, 2017, and issued Dec. 14, 2021, is directed to an electronic construction collaboration system for managing a construction project. The electronic construction collaboration system includes an Enterprise Resource Planning (ERP) sub-system including a contract engine configured to generate at least one project contract including a contract data set and ERP metadata corresponding to Building Information Modeling (BIM) metadata included in a structural object of a construction project model in a BIM sub-system and an interconnection engine configured to associatively link the ERP metadata and the BIM metadata and send the contract data set to the BIM sub-system in response to associatively linking the ERP metadata and the BIM metadata.

US Patent Publication No. 2023/0306153 for Method and system for the production of a building by inventors Klatte, et al., filed Dec. 20, 2022, and published Sep. 28, 2023, is directed to a method and a system for producing a building, which comprises at least one building subunit. In this case, technical boundary conditions for the production of a building are first generated in that a development area and country-specific building specifications are recorded and/or analyzed. On the basis of the technical boundary conditions, a building plan is created via a client-server model, a server device generating a building specification optimized for the technical boundary conditions via an algorithm of the harmonic search. Building measures for the building to be built are finally initiated on the basis of the building plan.

U.S. Pat. No. 12,175,163 for Systems and methods for creating and presenting planning, real estate, and infrastructure projects by inventor Wilts, filed Jun. 11, 2021, and issued Dec. 24, 2024, is directed to systems and methods for presenting digital infrastructure planning in a three-dimensional topographical format including presenting a Fiber Specification used to create a Fiber configuration, and in response to a selection in the Fiber Specification for a condition, presenting an Element Editor interface for the Fiber configuration which is specific to the selection for the condition in the Fiber Specification. Further, in response to a selection in the Element Editor for a Fiber configuration which is specific to the selection for the condition in the Fiber Specification, presenting configuration options for a conduit in the Element Editor, in response to a selection for a configuration option for the conduit, presenting configuration options for the innerduct in the Element Editor, and in response to a selection from the configuration options for the innerduct, presenting options for the cable in the Element Editor.

US Patent Publication No. 2019/0205484 for Systems and methods for construction planning by inventors Morkos, et al., filed Dec. 29, 2017, and published Jul. 4, 2019, is directed to systems and methods for construction planning. The systems and methods may utilize construction recipes and recipe relationships between the construction recipes. A construction recipe may comprise a formula for building a construction element, and comprise one or more construction operations logically related by one or more logical relationships. The same construction recipe may be assigned to construction elements of the same type. An operation can be defined by required resources drawn from a resource pool.

### SUMMARY OF THE INVENTION

The present invention relates to construction planning and more specifically to preconstruction planning and management utilizing artificial intelligence (AI).

It is an object of this invention to provide an all-in-one AI-powered preconstruction platform to coordinate personnel and/or services and streamline a construction project from planning to approval.

In one embodiment, the present invention includes a method for automated preconstruction management, including receiving, by a computer processor including a memory, a street address of a property, conducting, by an artificial intelligence (AI) engine, analysis of the property by retrieving property data for the street address from at least one public record database, retrieving, by the AI engine, assessor data for the street address from at least one additional public record database, wherein the assessor data includes at least one image of the property, performing, by the AI engine, project scoping, wherein the AI engine receives at least one project input, wherein the AI engine is operable to generate at least one question based on the at least one project input, receiving, by the AI engine, at least one natural language description, wherein the at least one natural language description includes at least one proposed change to the property, creating, by the AI engine, a project for the property based on the at least one project input, wherein the project for the property includes predetermined parameters and the at least one proposed change on an interactive map, generating, by the AI engine, at least one floor plan for the project based on the at least one natural language description, displaying the interactive map via a graphical user interface (GUI) on at least one device, searching at least one zoning database, by the AI engine, for at least one zoning rule for the street address, conducting, by the AI engine, compliance validation analysis of the project by referencing the at least one zoning rule for the street address against the at least one proposed change to the property, automatically adjusting, by the AI engine, the at least one floor plan for the project based on the compliance validation analysis, and submitting, by the AI engine, at least one permit application to a municipality for approval.

In another embodiment, the present invention includes a system for automated preconstruction management, including, a server platform with a processor including a memory and the server platform includes at least one artificial intelligence (AI) engine, wherein the at least one processor is operable to receive a street address of a property, wherein the AI engine is operable to conduct analysis of the property by retrieving property data for the street address from at least one public record database, wherein the AI engine is operable to retrieve assessor data for the street address from at least one additional public record database, wherein the assessor data includes at least one image of the property, wherein the AI engine is operable to perform project scoping, wherein the AI engine is operable to receive at least one project input, wherein the AI engine is operable to generate at least one question based on the at least one project input, wherein the AI engine is operable to receive at least one natural language description, wherein the at least one natural language description includes at least one proposed change to the property, wherein the AI engine is operable to create a project for the property based on the at least one project input, wherein the project for the property includes predetermined parameters and the at least one proposed change on an interactive map, wherein the AI engine is operable to generate at least one floor plan for the project based on the at least one natural language description, wherein the interactive map is displayed via a graphical user interface (GUI) on at least one user device, wherein the AI engine is operable to search at least one zoning database for at least one zoning rule for the street address, wherein the AI engine is operable to conduct compliance validation analysis of the project by referencing the at least one zoning rule for the street address against the at least one proposed change to the property, wherein the AI engine is operable to automatically adjust the at least one floor plan for the project based on the compliance validation analysis, and wherein the AI engine is operable to submit at least one permit application to a municipality for approval.

In yet another embodiment, the present invention includes a method for automated preconstruction management, including, receiving, by a computer processor including a memory, a street address of a property, conducting, by an artificial intelligence (AI) engine, analysis of the property by retrieving property data for the street address from at least one public record database, retrieving, by the AI engine, assessor data for the street address from at least one additional public record database, wherein the assessor data includes at least one image of the property, performing, by the AI engine, project scoping, wherein the AI engine receives at least one project input, wherein the AI engine is operable to generate at least one question based on the at least one project input, receiving, by the AI engine, at least one natural language description, wherein the at least one natural language description includes at least one proposed change to the property, creating, by the AI engine, a project for the property based on the at least one project input, wherein the project for the property includes predetermined parameters and the at least one proposed change on an interactive map, generating, by the AI engine, at least one floor plan for the project based on the at least one natural language description, displaying the interactive map via a graphical user interface (GUI) on at least one device, searching at least one zoning database, by the AI engine, for at least one zoning rule for the street address, conducting, by the AI engine, compliance validation analysis of the project by referencing the at least one zoning rule for the street address against the at least one proposed change to the property, automatically adjusting, by the AI engine, the at least one floor plan for the project based on the compliance validation analysis, submitting, by the AI engine, at least one permit application to a municipality for approval, monitoring, by the AI engine, project progress in real time, and automatically adjusting, by the AI engine, a project timeline based on the monitored project progress.

These and other aspects of the present invention will become apparent to those skilled in the art after a reading of the following description of the preferred embodiment when considered with the drawings, as they support the claimed invention.

### BRIEF DESCRIPTION OF THE DRAWINGS

FIG. 1A illustrates a schematic diagram of a system of a preconstruction platform of the present invention.

FIG. 1B illustrates a schematic diagram of a system of a preconstruction platform of the present invention.

FIG. 2 illustrates a block diagram of the steps performed by a platform of the present invention for the preconstruction process.

FIG. 3 illustrates an additional block diagram of the steps performed by a platform of the present invention.

FIG. 4 is a schematic diagram of a system of the present invention.

### DETAILED DESCRIPTION

The present invention is generally directed to construction planning and more specifically to preconstruction planning and management utilizing AI.

In one embodiment, the present invention includes a method for automated preconstruction management, including receiving, by a computer processor including a memory, a street address of a property, conducting, by an artificial intelligence (AI) engine, analysis of the property by retrieving property data for the street address from at least one public record database, retrieving, by the AI engine, assessor data for the street address from at least one additional public record database, wherein the assessor data includes at least one image of the property, performing, by the AI engine, project scoping, wherein the AI engine receives at least one project input, wherein the AI engine is operable to generate at least one question based on the at least one project input, receiving, by the AI engine, at least one natural language description, wherein the at least one natural language description includes at least one proposed change to the property, creating, by the AI engine, a project for the property based on the at least one project input, wherein the project for the property includes predetermined parameters and the at least one proposed change on an interactive map, generating, by the AI engine, at least one floor plan for the project based on the at least one natural language description, displaying the interactive map via a graphical user interface (GUI) on at least one device, searching at least one zoning database, by the AI engine, for at least one zoning rule for the street address, conducting, by the AI engine, compliance validation analysis of the project by referencing the at least one zoning rule for the street address against the at least one proposed change to the property, automatically adjusting, by the AI engine, the at least one floor plan for the project based on the compliance validation analysis, submitting, by the AI engine, at least one permit application to a municipality for approval, wherein the property data includes an assessor parcel number (APN), a lot size, a zoning designation, property boundary coordinates, an existing building square footage, a year of build, financial data, and/or ownership information, wherein the at least one zoning rule includes a setback requirement, a maximum lot coverage, a maximum building height, a maximum number of building stories, and/or an accessory dwelling unit (ADU) regulation, wherein the at least one question is related to a project type, an approximate square footage, a structural change, a plumbing change, and/or an electrical panel upgrade, wherein the predetermined parameters include property boundaries, setback lines, existing structure footprints, buildable area, and/or lot coverage, further comprising calculating, by the AI engine, types and quantities of materials required for the project based on the proposed changes, further comprising monitoring, by the AI engine, project progress in real time and further comprising automatically adjusting, by the AI engine, a project timeline based on the monitored project progress, further comprising receiving at least one proposal from at least one project vendor, and further comprising saving, by the AI engine, the analysis in at least one database.

In another embodiment, the present invention includes a system for automated preconstruction management, including, a server platform with a processor including a memory and the server platform includes at least one artificial intelligence (AI) engine, wherein the at least one processor is operable to receive a street address of a property, wherein the AI engine is operable to conduct analysis of the property by retrieving property data for the street address from at least one public record database, wherein the AI engine is operable to retrieve assessor data for the street address from at least one additional public record database, wherein the assessor data includes at least one image of the property, wherein the AI engine is operable to perform project scoping, wherein the AI engine is operable to receive at least one project input, wherein the AI engine is operable to generate at least one question based on the at least one project input, wherein the AI engine is operable to receive at least one natural language description, wherein the at least one natural language description includes at least one proposed change to the property, wherein the AI engine is operable to create a project for the property based on the at least one project input, wherein the project for the property includes predetermined parameters and the at least one proposed change on an interactive map, wherein the AI engine is operable to generate at least one floor plan for the project based on the at least one natural language description, wherein the interactive map is displayed via a graphical user interface (GUI) on at least one user device, wherein the AI engine is operable to search at least one zoning database for at least one zoning rule for the street address, wherein the AI engine is operable to conduct compliance validation analysis of the project by referencing the at least one zoning rule for the street address against the at least one proposed change to the property, wherein the AI engine is operable to automatically adjust the at least one floor plan for the project based on the compliance validation analysis, wherein the AI engine is operable to submit at least one permit application to a municipality for approval, wherein the property data includes an assessor parcel number (APN), a lot size, a zoning designation, property boundary coordinates, an existing building square footage, a year of build, financial data, and/or ownership information, wherein the at least one zoning rule includes a setback requirement, a maximum lot coverage, a maximum building height, a maximum number of building stories, and/or an accessory dwelling unit (ADU) regulation, wherein the predetermined parameters include property boundaries, setback lines, existing structure footprints, buildable area, and/or lot coverage, wherein the system is operable to receive at least one proposal from at least one project vendor, wherein the AI engine is operable to monitor project progress in real time, and wherein the AI engine is further operable to automatically adjust a project timeline based on monitored project progress.

In yet another embodiment, the present invention includes a method for automated preconstruction management, including, receiving, by a computer processor including a memory, a street address of a property, conducting, by an artificial intelligence (AI) engine, analysis of the property by retrieving property data for the street address from at least one public record database, retrieving, by the AI engine, assessor data for the street address from at least one additional public record database, wherein the assessor data includes at least one image of the property, performing, by the AI engine, project scoping, wherein the AI engine receives at least one project input, wherein the AI engine is operable to generate at least one question based on the at least one project input, receiving, by the AI engine, at least one natural language description, wherein the at least one natural language description includes at least one proposed change to the property, creating, by the AI engine, a project for the property based on the at least one project input, wherein the project for the property includes predetermined parameters and the at least one proposed change on an interactive map, generating, by the AI engine, at least one floor plan for the project based on the at least one natural language description, displaying the interactive map via a graphical user interface (GUI) on at least one device, searching at least one zoning database, by the AI engine, for at least one zoning rule for the street address, conducting, by the AI engine, compliance validation analysis of the project by referencing the at least one zoning rule for the street address against the at least one proposed change to the property, automatically adjusting, by the AI engine, the at least one floor plan for the project based on the compliance validation analysis, submitting, by the AI engine, at least one permit application to a municipality for approval, monitoring, by the AI engine, project progress in real time, automatically adjusting, by the AI engine, a project timeline based on the monitored project progress, wherein the property data includes an assessor parcel number (APN), a lot size, a zoning designation, property boundary coordinates, an existing building square footage, a year of build, financial data, and/or ownership information, wherein the at least one zoning rule includes a setback requirement, a maximum lot coverage, a maximum building height, a maximum number of building stories, and/or an accessory dwelling unit (ADU) regulation, wherein the predetermined parameters include property boundaries, setback lines, existing structure footprints, buildable area, and/or lot coverage, and further comprising calculating, by the AI engine, types and quantities of materials required for the project based on the proposed changes.

None of the prior art discloses an all-in-one AI-powered preconstruction system and platform to automate the preconstruction process, including, discovering, capturing, designing, engineering, procuring, permitting, and/or supporting services, and streamline a construction project from planning to approval. Additionally, none of the prior art discloses AI-powered preconstruction system and platform operable to perform autonomous property analysis, project scoping with conversational AI, or automatic extraction of assessor data, including building or property images, for the property from public records.

The construction industry in the United States alone is a $2 trillion industry, yet it is one of the most inefficient and outdated industries. Municipalities continue to rely on paper plans, manual, slow, and inefficient workflows, fragmented communication, and the permitting process is slow and unpredictable.

Preconstruction, also referred to as pre-con, is the process of planning and preparation that takes place before actual construction beings. Preconstruction generally includes the creation of a construction plan, designing, engineering, procurement, and permitting. Since preconstruction sets up a construction project from the beginning, it is imperative that the preconstruction process is efficient, both in time and resources, as well as accurate, and thorough.

However, there is no existing service or platform that offers an automated preconstruction process. Preconstruction, like construction in general, generally suffers from manual workflows, paper-based processes, outdated permitting, fragmented communication, delayed timelines, budget overruns, and/or disconnected tools. Thus, there is a need for a centralized preconstruction platform to automate the preconstruction process from initial site research to final permitting and to streamline communications and collaboration between users.

Therefore, it is an object of this invention to provide an AI-powered preconstruction platform, integrating AI-powered designing, engineering, compliance, and municipal permitting.

Referring now to the drawings in general, the illustrations are for the purpose of describing one or more preferred embodiments of the invention and are not intended to limit the invention thereto.

The platform is operable to utilize a plurality of learning techniques including, but not limited to, machine learning (ML), artificial intelligence (AI), deep learning (DL), neural networks (NNs), artificial neural networks (ANNs), support vector machines (SVMs), Markov decision process (MDP), and/or natural language processing (NLP). The platform is operable to use any of the aforementioned learning techniques alone or in combination.

Further, the platform is operable to utilize predictive analytics techniques including, but not limited to, machine learning (ML), artificial intelligence (AI), neural networks (NNs) (e.g., long short-term memory (LSTM) neural networks), deep learning, historical data, and/or data mining to make future predictions and/or models. The platform is preferably operable to recommend and/or perform actions based on historical data, external data sources, ML, AI, NNs, and/or other learning techniques. The platform is operable to utilize predictive modeling and/or optimization algorithms including, but not limited to, heuristic algorithms, particle swarm optimization, genetic algorithms, technical analysis descriptors, combinatorial algorithms, quantum optimization algorithms, iterative methods, deep learning techniques, and/or feature selection techniques.

In one embodiment, the present invention is operable to provide an artificial intelligence preconstruction platform, wherein the platform provides automated property analysis, compliance, rendering, designing, engineering, permitting, procurement, and/or inspection/handoff services throughout the preconstruction process.

In one embodiment, the platform is operable to provide automated property analysis, compliance, rendering, designing, engineering, and permitting services for residential, commercial, and/or multifamily properties. In one embodiment, the platform is operable to provide automated property analysis, compliance, rendering, designing, engineering, and permitting services for new construction builds, remodels of existing structures, and/or additions to existing structures.

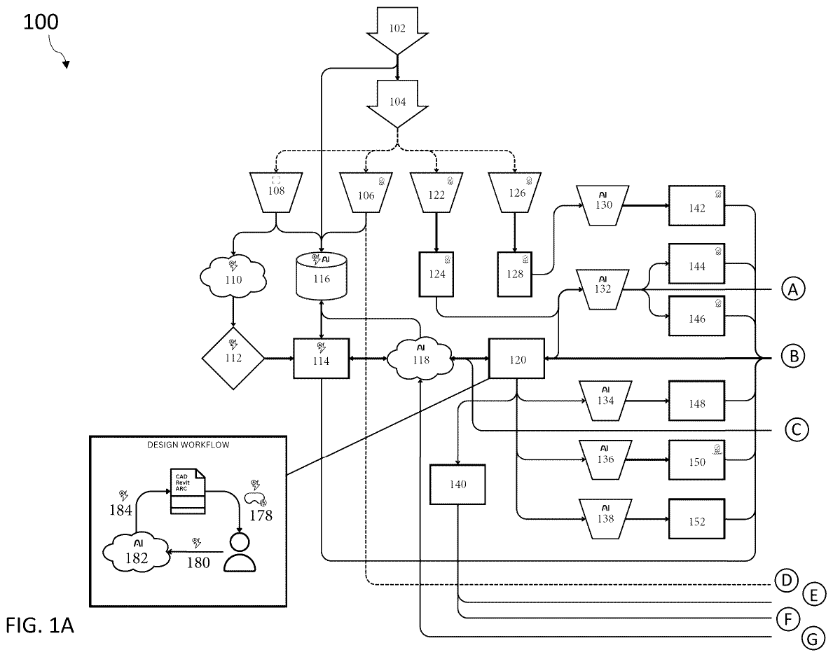

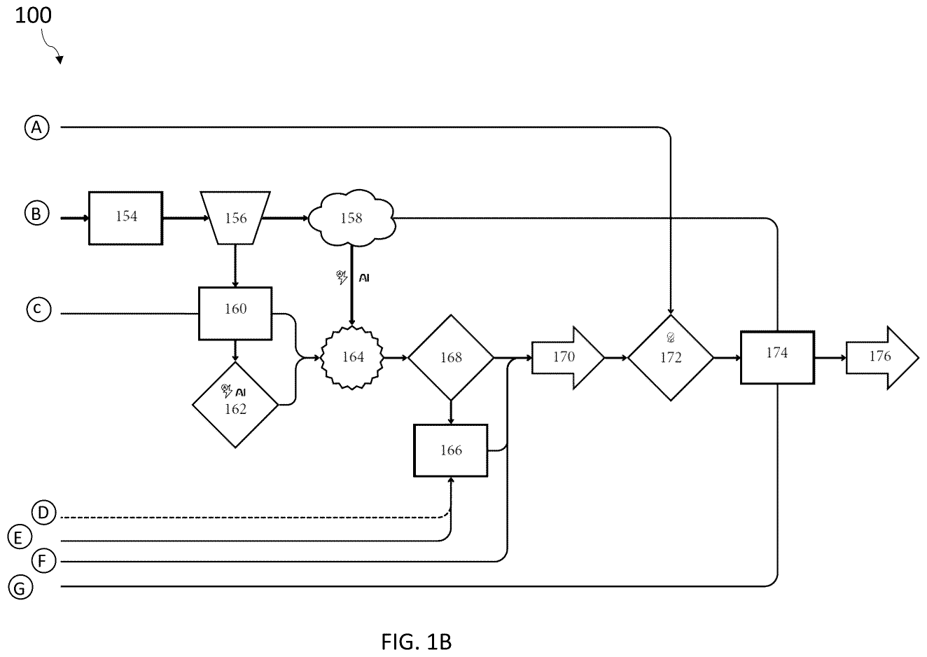

FIGS. 1A-1B illustrate a schematic diagram of a system 100 of a preconstruction platform of the present invention. In one embodiment, an address and/or a parcel number is input into the system 102. In one embodiment, project specific requirements are input into the system 104, including the type of project, including but not limited to, a new constriction, a remodel, or an addition. In one embodiment, 3D laser scanning 108 is used to capture the conditions of the land and/or the existing structure on the land of the project. In one embodiment, the laser scanning produces point cloud data, wherein the platform is operable to process the point cloud data 110. In one embodiment, the platform is operable to convert the point cloud data into 2D computer aided design (CAD) drawings/models 112, wherein the platform is further operable to convert the 2D models into 3D models. In one embodiment, the platform is further operable to produce as-built documentation 114 of the existing structure and/or land of the project. In one embodiment, the platform is operable to automatically analyze the 3D laser scans 108 and/or a site survey 106 of the land with building codes, municipal ordinances, and/or any site-specific regulations 116 to determine compliance of the land and/or existing structure with city/municipality regulations. In one embodiment, after the as-built documentation is produced by the platform 114, the platform is operable to address specific compliance checks and utilize conversational artificial intelligence 118 to determine compliance with city regulations.

In one embodiment, the platform is operable to receive input of soil reports 124 based on conducted soil investigations 122. In one embodiment, the platform is operable to receive input of percolation reports 128 based on conducted soils percolation testing 126.

In one embodiment, the platform is operable to automate and produce design drawings 120, including design layouts, including, elevations, sections, roofing structures, electrical components, doors, and/or windows. In one embodiment, the design workflow for creating the design drawings 120 includes, a user viewing the designs 178, a user requesting a change 180, the platform conducting automatic compliance checks for the requested change 182, and creating a new design drawing for the user to view 184. In one embodiment, the platform is operable to produce a demolition plan 140 based on the design drawings 120.

In one embodiment, the platform is operable to automate engineering services, including septic engineering 130, structural engineering 132, mechanical engineering 134, electrical engineering 136, and/or plumbing engineering 138. In one embodiment, the platform is operable to automatically generate septic designs 142, foundations plans 144, framing plans 146, mechanical plans 148, electric plans 150, and/or plumbing plans 152, based on the automated engineering conducted by the platform.

In one embodiment, the platform is operable to automate permit generation 154. In one embodiment, the platform is operable to integrate with the Register of Contractors (ROC), wherein an ROC assignment 156 can be automatically reflected in the system of the platform. In one embodiment, the platform is operable to automatically submit completed permit applications to the city/municipality 158.

In one embodiment, the platform is operable to automatically compile construction documents and/or construction plans 160. In one embodiment, the platform is operable to integrate with procurement platforms and/or automatically provide procurement recommendations 162 based on the construction plans and models. In one embodiment, once permit approval is granted 164, the platform is further operable to provide inspection and support services 168. In one embodiment, the platform is operable to provide automated site preparation and/or survey staking 166. Once construction begins 170, the platform is operable to provide support services for special inspections 172, and construction, requests for information (RFIs), and field changes 174. In one embodiment, the platform is operable to provide as-built documentation of the construction project 176.

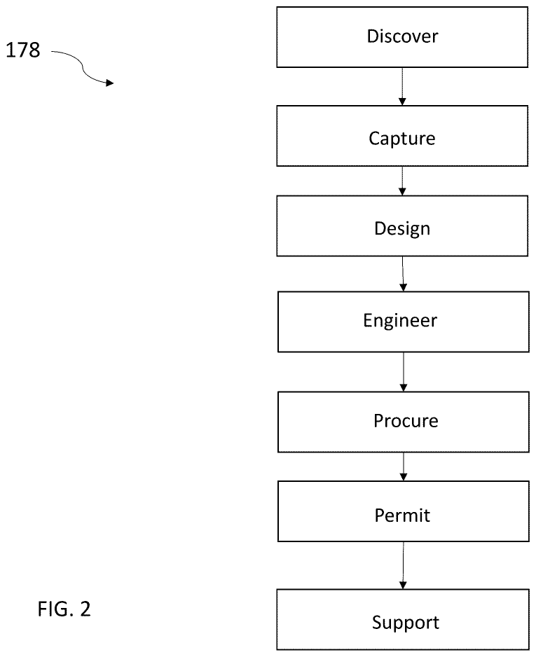

FIG. 2 illustrates a block diagram of the steps and/or services performed by the platform of the present invention for a construction project, generally described as 178. In one embodiment, the present invention is operable to provide an artificial intelligence preconstruction platform, wherein the platform provides automated discovery, capture/rendering, designing, engineering, procurement, procurement, and/or inspection/handoff services throughout the preconstruction process. In one embodiment, the automated discovery includes property analysis and project scoping. In one embodiment, the automated capture/rendering includes the generation of a visualization such as an interactive project map.

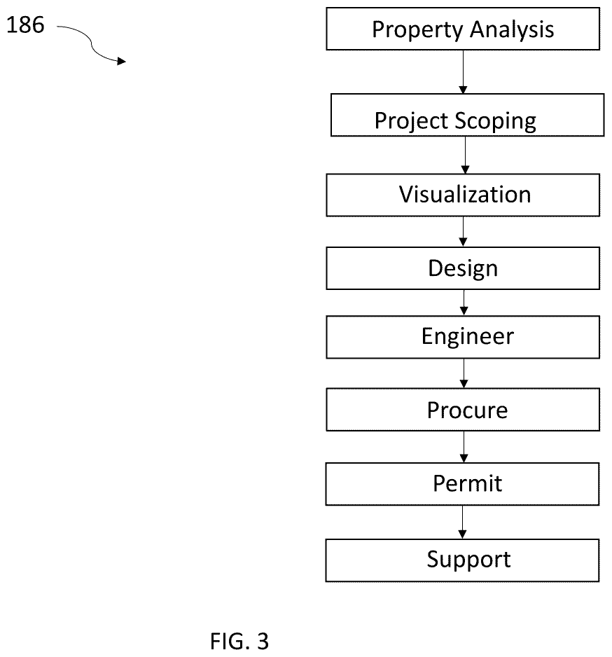

FIG. 3 illustrates an additional block diagram of the steps performed by a platform of the present invention, generally described as 186. In one embodiment, the present invention is operable to provide a system and/or method for automated preconstruction management, wherein the system and/or method for automated preconstruction management includes property analysis, project scoping, generation of a visualization such as an interactive project map, designing, engineering, procurement, permitting, and other support throughout the preconstruction process.

### Property Analysis

In one embodiment, the platform is operable to perform a comprehensive property feasibility analysis based on a single address or location. In one embodiment, at least one map is automatically integrated into the address input, such as GOOGLE MAPS. In one embodiment, the platform includes at least one AI engine operable to execute a property feasibility analysis from a single address input. First, the platform is operable to retrieve property data through an API call with the street address, wherein the platform is operable to retrieve a plurality of property information, including but not limited to the assessor parcel number (APN), lot size, zoning designation, property boundary coordinates as GeoJSON, existing building square footage, year of build, financial data such as land value, improvement value, previous/last sale price, and/or owner information.

Second, the platform is operable to search for applicable zoning rules, wherein the platform is operable to query a municipal zoning database, wherein the platform is operable to retrieve applicable zoning rules and/or information, including but not limited to, setback requirements, maximum lot coverage percentage, maximum building height and stories, accessory dwelling unit (ADU) regulations, maximum count, maximum size, ADU-specific setback requirements, ADU height restrictions, and/or parking requirements.

Next, the platform is operable to extract data from at least one external database, wherein the external database is a public records database. In a preferred embodiment, the platform is operable to extract assessor data for the property from at least one public record database. In one embodiment, the platform includes a web crawler, wherein the web crawler is operable to crawl the Internet to find zoning rules for a specified address, wherein the web crawler is further operable to crawl the Internet to find building/structure blueprints, drawings, and/or sketches for a specified address, wherein the web crawler is further operable to crawl the Internet to find any public data for a specified address. In one embodiment, the platform is operable to use headless browser automation to navigate to county assessor websites, wherein the platform is operable to capture building sketch images and apply AI computer vision to the building sketch images to extract structured building data, thereby solving a known issue or programmatically accessing building information that only exists as visual architectural drawings on government websites with no API. In one embodiment, the extracted structured building data includes, but is not limited to, existing structures, floor plans, number of floors, walls, and/or dimensions.

In one embodiment, the platform is operable to launch a headless browser, wherein the assessor parcel number (APN) is a query parameter, wherein the platform is operable to autonomously navigate to a county assessor website for the property, wherein the platform is operable to enter the APN and capture a full-page screenshot of the building/property sketch. In one embodiment, the platform is operable to capture a full-page screenshot. In one embodiment, the platform is further operable to send the screenshot to the AI engine with a prompt to instruct the AI engine to identify each building section, such as the first floor, second floor, garage, and/or additions, extract square footage per section, determine which sections are ground-level for lot coverage calculations versus upper floors, and/or calculate a total footprint area. In one embodiment, the extracted and identified data is stored in at least one database, wherein the at least one database is structured in a JavaScript Object Notation (JSON) format. In one embodiment, the extracted and identified data stored in the at least one database is linked to an authenticated user via a user ID key. In one embodiment, the at least one database is the zoning database as described herein.

In one embodiment, the platform includes a smart caching system operable to ensure that each property is scraped only once, wherein subsequent requests return cached data from the at least one database. In one embodiment, a force-refresh parameter allows re-scraping if needed, such as when assessor records have been updated.

In one embodiment, the platform is operable to automatically create at least one shape on an interactive property map, thereby illustrating and visualizing existing building footprints based on the extracted dimensions.

Next, the platform is operable to automatically calculate a buildable area using the lot size, maximum coverage percentage, and existing building footprint. In one embodiment, the platform is further operable to calculate a maximum buildable area (e.g., lot size multiplied by coverage limit), current lot coverage (e.g., existing ground-floor footprint only), remaining buildable area, and current lot coverage percentage.

The platform is then operable to automatically perform a feasibility analysis using at least one AI engine, wherein the AI engine is operable to determine feasibility for each project type, such as ADU, an addition, second story, pool, etc., wherein the AI engine is operable to output a rating for each feasibility analysis. In one embodiment, the output is rated as high, medium, low, and not feasible. In another embodiment, the AI engine is operable to automatically calculate the maximum allowable size for each project type, estimated cost ranges, key permit requirements, potential issues, development opportunities, estimated timeline, and/or an overall recommendation for the project. In one embodiment, the overall recommendation for the project includes proceed, proceed with caution, or a no-go recommendation. The AI engine is operable to receive the assessor building sections data as described herein, wherein the AI engine is operable to correctly identify existing conditions such as whether the property already has a second story.

The platform is further operable to compile the complete analysis into a structured JSON object, wherein the platform is operable to save the completed analysis in at least one database, wherein the platform is further operable to stream the saved completed analysis to a frontend GUI via server-sent events (SSE). In one embodiment, the frontend GUI is operable to display animated progress cards that are operable to transform from pending to running to complete as each step of the project is completed.

In one embodiment, the platform is operable to retrieve property data through an API call, wherein the API call implements an API endpoint that accepts an address and returns the data using the SSE protocol. In one embodiment, the platform is operable to emit a JSON event containing the step number, status (e.g., running, complete, error), data payload, and/or timestamp for each step of the property analysis previously described herein. In another embodiment, the frontend GUI is operable to consume the data stream and render real-time progress visualization with animated cards for each step of the property analysis.

In one embodiment, the platform is operable to save completed analyses in at least one database. In one embodiment, the platform is operable to save all project data in an audit log with before/after values, source attribution, and/or timestamps. In one embodiment, changes to the project scope trigger automatic changes in the audit log. For example, if a project type is removed, such as removing “ADU” from the scope, the platform is operable to identify all related task categories and soft deletes the task categories while preserving the audit trail, logging the number of tasks affected and cost impacts, as well as updating the project phases accordingly.

### Project Scoping

In one embodiment, the platform is operable to retrieve the database record generated during the property analysis. Based on the database record, the platform is operable to utilize an AI engine to perform at least one action. In one embodiment, the AI engine is operable to display a property summary, wherein the property summary includes, but is not limited to, the address, zoning district, lot size, buildable area, existing buildings, and/or overall assessment. In another embodiment, the AI engine is operable to generate a contextual first message referencing specific property data. In another embodiment, the AI engine is operable to send the full analysis data to the platform so that each response from the AI engine or additional AI engines include property content and can reference specific zoning rules, buildable area, and/or feasibility determinations.

In one embodiment, the platform is operable to generate project scoping questions after the property analysis is complete through a conversational AI engine. In one embodiment, the AI engine is operable to generate project questions, automatically infer professional requirements such as surveys, structural engineering, permits, and/or soil reports, and/or create structured project specifications in at least one database. The structured project specification stored in the at least one database can include an address, APN, coordinates (latitude, longitude), lot size, zoning designation, existing building square footage, buildable area calculations (as JSON), the complete feasibility report (as JSON), overall assessment (GO, PROCEED_WITH_CAUTION, NO_GO), and optional project ID foreign key.

In one embodiment, the AI engine is operable to present pre-computed response options to the generated questions. In one embodiment, the generated questions include, but are not limited to, project type selection, approximate square footage, structural changes, plumbing work, electrical panel upgrades, and/or site work requirements. The platform is operable to receive user input, wherein the input includes answers to the generated questions. The platform is further operable to send the received user input through a requirement inference engine, which applies jurisdiction-specific rules to automatically generate project requirements. For example, if the project type includes ‘ADU’ and the jurisdiction is Phoenix R1-10 zoning, the AI engine automatically adds: Topographic Survey ($800-$1,200, 5-7 days), Structural Engineering Plans ($2,500-$4,000, 10-14 days), Soils Report ($1,500-$2,500, 7-10 days), and zone-specific setback requirements. In one embodiment, each requirement includes transparent reasoning explaining why it was added.

In one embodiment, the AI engine is operable to use an address of a property and query an API call for property data, wherein the AI engine is further operable to incorporate the specific zoning information into the generated questions and analysis. In one embodiment, the AI engine is operable to reference exact setback distances, lot coverage limits, and/or ADU regulations for the specific zoning district. In an alternative embodiment, the platform is operable to integrate with the API call to retrieve the building square footage from the county records.

After the completion of the project scoping, the platform is operable to automatically generate an interactive project map via the AI engine. In one embodiment, the AI engine is operable to automatically link the analysis record to the project via a project ID foreign key. In one embodiment, the interactive property map includes property boundaries, setback lines, existing building footprints, buildable area, and/or lot coverage. For example, an interactive property map can include setback lines calculated from the zoning database for front, rear, left, and right sides, existing building footprints from the assessor scraper shown as shapes, buildable area overlay in green, and lot coverage tracking that accounts for existing structures. In one embodiment, the platform is operable to receive real-time input to the interactive property map, wherein the input includes drawings of proposed structures, wherein the drawings of proposed structures are based on templates of structures.

### Compliance

In one embodiment, the platform is operable to provide real-time compliance validation analysis, wherein the real-time compliance validation analysis is displayed via an interactive property map.

In one embodiment, the platform is operable to perform continuous compliance validation analysis through setback validation, lot coverage monitoring, and/or per-side setback editing.

In one embodiment, setback validation includes color-coded setback lines on the interactive property map with dimension labels. The platform is operable to retrieve setback distances from a municipal zoning database based on the property's zoning district. The platform is operable to receive input for changes to the setback distances using the interactive property map, wherein if the received input encroaches into a setback zone, the platform is operable to automatically detect the violation and provide visual feedback, wherein the buildable area is rendered as a color-coded overlay on the interactive property map showing exactly where structures can be placed according to the setback requirements.

In one embodiment, the platform is operable to track the total lot coverage in real-time to perform the lot coverage monitoring. In one embodiment, the platform is operable to receive input for changes to the lot coverage using the interactive property map, wherein the platform is operable to automatically recalculate the coverage percentage instantly upon receiving input.

In one embodiment, the platform is operable to receive input for changes to setback distances per side using the interactive property map, wherein the input triggers the platform to immediately recalculate the buildable area and compliance status.

In one embodiment, the platform is operable to automatically analyze property analytics, coding, and/or regulatory data for any US-based address based on publicly available information. In one embodiment, the platform is operable to receive a US-based address of a property, wherein the platform is then operable to retrieve regulatory information and data related to the property. In one embodiment, the regulatory information and data related to the address includes, but is not limited to, parcel number, existing zoning codes, other applicable codes, setbacks, lot coverage percentage, building height thresholds, parking requirements, current owner(s), past owner(s), title documents, land use designation, council district, gross acreage, environmental data including hillside, floodplain, landscape setbacks, and/or other environmental data, and/or any other publicly available information regarding the property.

In one embodiment, the platform is operable to automatically generate an address-based and/or parcel-based plan for a property, wherein the plan automatically overlays property boundaries, property setbacks, allowable footprints, potential restrictions based on a zoning classification, publicly-available county information, maximum building height restrictions, allowance lot coverages, required easements, right-of-way constraints, including sidewalks and power line easements, floodplain overlays, environmental overlays, parking requirements, ingress and/or egress restrictions, land use map overlays showing surrounding property zoning for contextual analysis, local fire code constraints, and/or any other code and/or compliance overlay.

In one embodiment, the platform is operable to automatically generate a site map of a property, wherein the platform is operable to overlay parcel boundaries and/or existing structure on the site map.

In one embodiment, the platform is operable to generate on-site utility availability mapping, wherein the platform integrates city sewer, water, gas, electrical infrastructure, and/or other utility maps into the platform's analysis of the property. In one embodiment, the platform is operable to utilize geographic information system (GIS) and/or municipal databases to show underground utility locations and/or availability for tie-ins to the utility. In one embodiment, the platform is operable to automatically generate service request forms for new utility connections and/or modifications.

In one embodiment, the platform is operable to predict zoning and/or permitting issues based on proposed construction plans. In one embodiment, the platform is operable to identify and/or alert for potential violations of zoning and/or permits based on changes made during the designing stage. In one embodiment, the platform is operable to identify common permit rejection risks, including but not limited to, zoning noncompliance, utility conflicts, and/or environmental restrictions. In one embodiment, the platform is operable to provide automated zoning variance recommendations. In one embodiment, the platform is operable to automatically recommend code-compliant design modifications to reduce the risk of permit delays and/or denials.

In one embodiment, the platform is operable to predict a permit approval likelihood by analyzing historical municipal approval and/or rejection patterns for similar construction projects. In one embodiment, the platform uses historical permit outcome data from public municipal sources to predict a permit approval likelihood.

In one embodiment, the platform is operable to automatically update the construction project compliance analysis based on compliance and zoning updates from the municipality.

In one embodiment, the platform is operable to perform environmental compliance analysis, wherein the platform is operable to determine if a construction project meets local, state, and/or federal environmental requirements. In one embodiment, the platform is operable to determine if a construction project will require environmental impact mitigation.

In one embodiment, the platform is operable to perform energy code compliance analysis, wherein the platform is operable to determine if a construction project meets state, local, and/or federal energy efficiency standards/requirements.

In another embodiment, the platform is operable to perform Americans with Disabilities Act (ADA) compliance analysis.

In one embodiment, the platform is operable to integrate with a municipality's application programming interface (API), wherein the platform is further operable to provide real-time zoning and/or code enforcement updates. In one embodiment, the platform is operable to cross-reference code, in real-time, for designing, engineering, and/or permitting services.

### Zoning Database

In one embodiment, the platform is operable to include at least one database for storing jurisdiction-specific zoning regulations. Advantageously, the zoning database is operable to store zoning regulations as structured fields that can be programmatically queried by an AI engine for real-time compliance validation during design and/or for feasibility analysis during property analysis.

In one embodiment, the platform includes jurisdiction detection logic that is operable to identify the correct municipality for a given address, including unincorporated areas that fall under county rather than city zoning rules.

In one embodiment, the zoning database can include, but is not limited to, setback requirements, including front, rear, and side setback requirements, maximum lot coverage, maximum building height, including in feet and in stories, minimum lot dimensions (size, width, depth), ADU regulations including allowed/prohibited status, maximum ADU count, maximum ADU size in square feet, ADU-specific setbacks, and ADU height limits, parking requirements per unit, and/or covered parking mandates.

### Rendering

After the completion of the project scoping, the platform is operable to automatically generate an interactive project map via the AI engine, wherein the interactive project map enables interactive property visualization with real-time zoning compliance checking. In one embodiment, the platform is operable to retrieve and render satellite imagery of the actual property overlaid with property boundaries, setback lines, existing building footprints, and/or user-drawn proposed structures.

In one embodiment, the platform is operable to include at least four operating modes, wherein each operating mode is accessed via keyboard shortcuts and/or toolbar interactive elements, such as a button. The at least four operating modes include view mode, edit mode, draw mode, and measure mode. In view mode, the platform is operable to display all data as read-only. In edit mode, the platform is operable to enable boundary editing, edge labeling, and/or setback adjustments. In draw mode, the platform is operable to activate at least one drawing tool for user input. In one embodiment, the at least one drawing tool includes a rectangle tool, a polygon tool, a circle tool, and/or a polyline tool for distance measurement. In one embodiment, the platform is operable to automatically include alignment guides when in draw mode. In measure mode, the platform is operable to enable distance measurement between at least two points, wherein the platform is further operable to save and/or delete measurements.

In one embodiment, the platform is operable to include a plurality of templates, wherein each template includes an SVG architectural overlay rendering interior details, such as cars inside garages, beds inside bedrooms, and/or kitchen fixtures, wherein each template includes width and height parameters, wherein the platform is operable to scale all internal coordinates proportionally. The plurality of templates can include at least seven categories, including, but not limited to, garages (1-car, 2-car, 3-car, carport, RV pad), ADUs (studio, 1-bedroom, 2-bedroom, casita), pool(s) (rectangle, kidney, lap, spa), outdoor living (covered patio, arizona room, outdoor kitchen, pergola, sport court, fire pit), shed(s) (workshop, small, large), additions (primary bedroom, standard bedroom, primary bathroom, full bathroom, half bath, laundry room, home office, living room, kitchen), and new builds (small/medium/large ranch, L-shaped ranch, two-story narrow).

In one embodiment, the platform is operable to receive a natural language description including dimensions of proposed changes to a property, wherein the platform is operable to parse the dimensions.

In another embodiment, the platform is operable to include a grid overlay in the draw and edit modes, wherein the origin of the grid is calculated from the property structure's southwest corner, so grid lines align with the actual property rather than arbitrary map coordinates. In one embodiment, shapes can snap to grid intersections during drawing, wherein grid snapping takes priority over edge snapping when both are active by the platform. In another embodiment, the platform includes copy, paste, and/or duplicate tools on the interactive property map. In another embodiment, the platform includes undo and/or redo tools on the interactive property map. In another embodiment, the platform includes a PDF export tool on the interactive property map, wherein the platform is operable to capture the current map state as a screenshot and generate a PDF containing the property summary, map image, shapes table with dimensions, setback compliance status, and/or measurement data.

In one embodiment, light detection and ranging (LiDAR) is used to create as-built models of the land and/or existing property at/on the construction site. In one embodiment, the platform is operable to automatically register the LiDAR scans into a point cloud. In one embodiment, the platform is operable to automatically generate 2D as-built drawings in CAD, AUTODESK REVIT, and/or portable document format (PDF) file formats.

In one embodiment, the platform is operable to identify, classify, and/or structure a plurality of architectural and/or structural elements from raw LiDAR scan data. In one embodiment, the plurality of architectural and/or structural elements include, but are not limited to, walls, doors, foundation, windows, plumbing, electrical, heating, ventilation, and air condition (HVAC), and/or any other architectural elements. In one embodiment, the structural elements include, but are not limited to, walls, doors, foundation(s), cabinetry, plumbing fixtures, lights, outlets, fireplaces, a kitchen, a garage, and/or any other physical structure within a property structure.

In one embodiment, the platform is operable to automatically detect structural variations, wherein the platform is further operable to automatically generate digital as-built models, without requiring model redrafting.

In one embodiment, the platform is operable to convert LiDAR point cloud data into structured as-built floorplans. In one embodiment, the as-built floorplans are in the format of CAD, AUTODESK REVIT, and/or portable document format (PDF) files.

In one embodiment, the platform is operable to convert the 2D as-built drawings into a 3D model, including structural elements. In one embodiment, the 3D model includes an immersive visualization that enables interactive, web-based 3D walkthroughs, thus eliminating the need for local software installations. In one embodiment, the 3D model is directly compatible with 3D virtual-reality (VR) headsets for full-scale design exploration.

In one embodiment, the platform is operable to create a new 3D as-built file format, including an architectural rendering concept (ARC) format, wherein the ARC file format is specifically designed for as-built conditions. In one embodiment, the ARC file format allows universal 2D-to-3D conversions, wherein the 2D-to-3D conversions are viewable in both desktop and web environments. In one embodiment, the ARC file format advantageously supports seamless walkthroughs in a web browser and/or full-scale VR visualizations.

In one embodiment, the platform is operable to provide the 3D model in a viewable form, including a MATTERPORT 3D WALKTHROUGH.

In one embodiment, the platform is operable to compare scanned as-built conditions against original floor plans, wherein the platform is operable to detect undocumented modifications, out-of-plumb walls, load-bearing adjustments, and/or structural discrepancies. In one embodiment, the platform is operable to automatically generate risk reports based on structural alignment. In one embodiment, the platform is operable to automatically generate suggested corrections for structural alignment.

In one embodiment, the platform is operable to generate predictions of internal construction elements, wherein the internal construction elements include, but are not limited to, load-bearing structures, framing, concealed HVAC elements, concealed electrical elements, and/or concealed plumbing elements. In one embodiment, the predictions are based on the era in time in which the building was constructed, historical construction standards, available blueprints, municipal records, and/or similar LiDAR data sets over time. In one embodiment, the platform is operable to prepare digital twin approximations to support future design and/or engineering modifications.

In one embodiment, the platform is operable to integrate automated clash detection and/or component coordination analysis, wherein mechanical, engineering, and plumbing (MEP) interferences and/or structural concerns are identified. In one embodiment, the MEP interferences include, but are not limited to, ductwork conflicting with framing and/or plumbing obstruction. In one embodiment, the structural concerns include, but are not limited to, wall load issues, and/or beam misalignment. In one embodiment, the platform is operable to provide suggestions on design modifications to improve efficiency and reduce the costs of the project.

In one embodiment, the platform is compatible with VR, augmented reality (AR), and/or mixed reality environments. In one embodiment, the platform is operable to provide a VR/AR-compatible as-built model, wherein the model includes virtual walkthrough capabilities. Advantageously, the platform provides and enables immersive planning for construction projects.

In one embodiment, the platform includes a headset configured for virtual reality, augmented reality, and/or mixed reality environments (“AR/VR”). The headset preferably includes a display, an eyewear component, at least one power supply component, at least one image capturing device, and/or control electronics. In one embodiment, the headset is a pair of goggles. Alternatively, the headset is a pair of glasses. In one embodiment, the headset includes at least one strap and/or temples. In one embodiment, the power supply component includes at least one battery, at least one super capacitor, or other similar power supply components. In another embodiment, the battery includes at least one rechargeable battery. In yet another embodiment, the at least one rechargeable battery includes a lithium-ion battery.

In a preferred embodiment, the headset is configured to receive and display the as-built model, wherein the as-built model can further include proposed construction plans, including additions and/or remodels. The headset is configured to receive and display an image of a virtual scene, movie, and/or environment. The headset is further operable to receive audio data and communicate the audio data to a wearer via a speaker, headphones, and other similar audio playback devices. In one embodiment, the headphones are noise-cancelling headphones. The noise-cancelling headphones are configured to block out external noise such that the wearer is completely immersed in the AR/VR environment.

Examples of headsets and/or AR/VR systems include, but are not limited to, those described in U.S. Pat. Nos. 8,217,856; 8,743,145; 9,094,677; 9,223,136; 9,635,450; 9,671,614; 9,733,480; 9,734,402; 9,766,462; 9,846,483; 9,858,703; 9,897,812; 9,989,998; 10,025,060; 10,037,084; 10,055,645; 10,055,887; 10,061,352; 10,061,391; 10,082,672; 10,102,674; 10,122,990; 10,124,251; 10,133,305; 10,185,390; 10,209,769; 10,244,226; 10,254,547; 10,261,579; 10,318,007; 10,395,111; 10,419,731; 10,429,647; 10,452,911; 10,540,003; 10,656,423; 10,656,822; 10,701,342; 10,769,438; 10,825,255; 10,838,206; 10,843,067; 10,890,941; 10,911,734; 10,922,886; 10,928,613; 10,951,880; 10,979,681; 11,030,719; 11,055,879; 11,106,276; 11,145,031; 11,145,096; 11,159,713; 11,170,678; 11,217,021; 11,228,745; 11,275,945; 11,281,290; and 11,288,027 and U.S. Patent Publication Nos. 20200049946, 20210243384, and 20220130103, each of which is incorporated herein by reference in its entirety.

In one embodiment, the at least one strap is configured to wrap around a wearer's head and attach to the eyewear component via at least one attachment mechanism. The at least one attachment mechanism includes a hook and loop fastener, a latch, a button, a buckle, a snap, a tie, a clip, and other similar attachment mechanisms. The at least one strap is adjustable to a wearer's head. Advantageously, this allows the headset to be used for wearers of different head sizes. For example, and not limitation, the at least one strap includes a tightening mechanism. In one embodiment, the tightening mechanism is configured to rotate in one direction and increase the tension in the head strap and rotate in the opposite direction to loosen the tension in the head strap. In yet another embodiment, the at least one strap includes at least two straps. In one embodiment, the at least two straps do not overlap and are in a parallel position around a wearer's head. Alternatively, the at least two straps are configured to intersect in the center of the back of a wearer's head to provide a tighter fit.

Advantageously, the headset is configured to provide minimal pressure to a wearer's face. In one embodiment, the headset includes a nose component. In one embodiment, a wearer's nose is operable to rest inside the nose component. In one embodiment, the nose component is adjustable. In one embodiment, the nose component is configured to move left, right, up, and/or down. In one embodiment, the nose component is operable to expand. Alternatively, the headset is designed to rest on the ridge of the wearer's nose. In yet another embodiment, the headset covers a wearer's entire face.

In one embodiment, the at least one image capturing device is a motion sensor camera. In one embodiment, the motion sensor camera is configured to capture a wearer's body movement. Additionally, or alternatively, the at least one image capturing device includes a LIDAR camera. The at least one image capturing device is further operable to determine a wearer's positioning and provide at least one recommendation to correct a wearer's positioning based on the display.

The control electronics preferably include at least one processor. By way of example, and not limitation, the processor includes a general-purpose microprocessor (e.g., a central processing unit (CPU)), a graphics processing unit (GPU), a microcontroller, a Digital Signal Processor (DSP), an Application Specific Integrated Circuit (ASIC), a Field Programmable Gate Array (FPGA), a Programmable Logic Device (PLD), a controller, a state machine, gated or transistor logic, discrete hardware components, or any other suitable entity or combinations thereof that is operable to perform calculations, process instructions for execution, and/or other manipulations of information. In one embodiment, one or more of the at least one processor is operable to run predefined programs stored in at least one memory of the control electronics.

The control electronics preferably includes at least one antenna, which allows the control electronics to receive and process input data (e.g., AR/VR settings) from at least one remote device (e.g., smartphone, tablet, laptop computer, desktop computer). In a preferred embodiment, the at least one remote device is in wireless network communication with the control electronics. The wireless communication is, by way of example and not limitation, radio frequency, BLUETOOTH®, ZIGBEE®, WI-FI®, wireless local area networking, near field communication (NFC), or other similar commercially utilized standards. Alternatively, the at least one remote device is in wired communication with the control electronics through USB or equivalent.

In one embodiment, the at least one processor is a microcontroller. The microcontroller includes a transceiver, BLUETOOTH module, WI-FI module, a microprocessor, an ultra-low-power co-processor, read-only memory (ROM), random-access memory (RAM) (e.g., static random-access memory (SRAM)), flash memory, a power management unit, and/or a digital-to-analog converter.

In a preferred embodiment, the headset includes at least one sensor. The at least one sensor includes, but is not limited to, at least one gyroscope, at least one accelerometer, at least one magnetometer, and/or at least one eye tracker. The at least one sensor is preferably connected to the at least one processor. The at least one processor is operable to track and plot movement (e.g., user's head, user's eyes), for example, and not limitation, in an XYZ plane that is different from the at least one image capturing device. In one embodiment, the headset is operable to provide foveated rendering. Alternatively, the headset is operable to provide fixed foveated rendering.

In yet another embodiment, the AR/VR system is operable to receive wearer voice input data. The AR/VR system includes a microphone that is operable to receive and record a wearer's voice. The headset is further operable to change the display based on the wearer's words. For example, and not limitation, the AR/VR system is configured to receive the words “show me the model,” or the like, from a wearer, and activate the as-built model The headset is operable to communicate, preferably wirelessly, with at least one remote device including, but not limited to, a mobile phone or a tablet. The mobile phone is operable to be any mobile phone that (1) is capable of running mobile applications and (2) is capable of communicating with the headset. The mobile phone includes, for example, an ANDROID™ phone, an APPLE® IPHONE®, or a SAMSUNG® GALAXY® phone. Likewise, the tablet is operable to be any tablet that (1) is capable of running mobile applications and (2) is capable of communicating with the headset. The tablet includes, for example, the 3G or 4G version of the APPLE@ IPAD® or the 5G version of the Samsung Galaxy Tab S6.

Further in the AR/VR system, the remote device is in communication with a cellular network and/or a network. The network is operable to be any network for providing wired or wireless connection to the Internet, such as a local area network (LAN) or a wide area network (WAN).

In one embodiment, an AR/VR mobile application is installed and running at the remote device. The AR/VR system mobile application is implemented according to the type (i.e., the operating system) of remote device on which it is running. The AR/VR system mobile application is designed to receive wearer information from the headset. In one embodiment, the AR/VR mobile application is operable to provide graphical, audible, and/or tactile feedback to the wearer. In one embodiment, the AR/VR system is configured to develop a personalized profile based on a wearer's prior AR/VR environments and response.

The AR/VR system is operable to utilize a plurality of learning techniques including, but not limited to, machine learning (ML), artificial intelligence (AI), deep learning (DL), neural networks (NNs), artificial neural networks (ANNs), support vector machines (SVMs), Markov decision process (MDP), and/or natural language processing (NLP). The AR/VR system is operable to use any of the aforementioned learning techniques alone or in combination.

Further, the AR/VR system is operable to utilize predictive analytics techniques including, but not limited to, machine learning (ML), artificial intelligence (AI), neural networks (NNs) (e.g., long short term memory (LSTM) neural networks), deep learning, historical data, and/or data mining to make future predictions and/or models. The AR/VR system is preferably operable to recommend and/or perform actions based on historical data, external data sources, ML, AI, NNs, and/or other learning techniques. The AR/VR system is operable to utilize predictive modeling and/or optimization algorithms including, but not limited to, heuristic algorithms, particle swarm optimization, genetic algorithms, technical analysis descriptors, combinatorial algorithms, quantum optimization algorithms, iterative methods, deep learning techniques, and/or feature selection techniques.

### Designing

In one embodiment, the platform is operable to automate design iterations of a construction project. In one embodiment, the platform is operable to receive real-time modifications to the construction project design and automatically make the modifications in real-time to the construction project plans. In one embodiment, the platform is operable to allow real-time modification of the 3D model file within an interactive digital twin of the structure. In one embodiment, the modifications include, but are not limited to, resizing rooms, moving walls, adjusting fixtures, and/or exploring layout options within the immersive environment. In one embodiment, the platform is operable to determine, in real-time, if a proposed modification maintains structural feasibility before rendering updated plans.

In one embodiment, the platform is operable to generate new build designs based on user preferences. In one embodiment, the platform is operable to automatically generate a 3D model based on user inputs and/or sample images of preferred design aesthetics. For example, if a user inputs their preferences including a four-bedroom, 2-bathroom, modern home, the platform is operable to automatically generate a 3D model based on these user inputs.

In one embodiment, the platform is operable to automatically include real-world material data in the 3D model. In one embodiment, the real-world material data includes, but is not limited to, flooring, cabinets, countertops, lighting fixtures, doors, and/or windows.

In one embodiment, the platform is operable to receive user feedback, comments, and/or mark-ups on the 3D models of the construction project. In one embodiment, the platform is operable to provide interaction capabilities for a user to interact with the 3D model, wherein the user can make changes to the 3D model. In one embodiment, a user can make changes including, but not limited to, moving structures including walls, doors, and/or other fixtures, changing a layout of a room in real-time, and/or any other structural modifications. In one embodiment, the platform is operable to automatically synchronize the modifications of the 3D model to updated 2D CAD plans.

In one embodiment, the platform is operable to receive audio input indicating user changes to the 3D model. For example, a user can conversationally state “reduce bedroom 1 and expand bathroom 1,” wherein the platform is operable to automatically adjust the 3D model based on the user's verbal request. In one embodiment, the platform is operable to determine, in real-time, if a proposed modification maintains structural feasibility before rendering updated plans.

In one embodiment, the platform is operable to automatically suggest the optimal design approach to a construction project and/or automatically apply automated suggestions to the 3D model of the construction project.

In one embodiment, the platform is operable to automatically render the design from a 3D model into a 2D permit-ready plan, advantageously providing automated plan conversion to submit the plans to the city. In one embodiment, the platform is operable to maintain layered metadata in the 3D model ARC file format to provide instant compliance validation.

In one embodiment, the platform is operable to automatically generate cost estimates based on the 3D model. In one embodiment, the platform is operable to automatically provide procurement recommendations, based on the 3D model.

### Engineering

In one embodiment, the platform is operable to automate structural and MEP engineering, while simultaneously ensuring compliance with relevant codes and/or safety regulations. In one embodiment, the platform is operable to automate structural, electrical, plumbing, and/or mechanical engineering calculations.

In one embodiment, the platform is operable to use an AI engine to automatically generate structured floor plans from natural language descriptions, incorporate room dimensions, fixture placement, and/or circulation patterns derived from analysis of professional architectural plans. In one embodiment, the platform is operable to receive input, wherein the input includes natural language descriptions of a project, structure, or building. Based on the received input, the platform is operable to use an AI engine to automatically generate a floor plan with rooms, fixtures, doors, windows, and/or dimensions, wherein the platform is operable to render the floor plan as an interactive SVG with live preview, geometric transformations (rotate 90/180/270 degrees, flip horizontal/vertical), and placement on the property map with database persistence.

In one embodiment, the platform is operable to use an AI engine, wherein the AI engine is operable to receive a natural language description, wherein the AI engine is operable to generate a response containing room definitions with dimensions, fixture placements, door and window locations, and wall configurations, wherein the response is a JSON response. In one embodiment, the platform is operable to receive geometric transformation inputs, such as rotation at 90-degree increments, horizontal and vertical flip.

In one embodiment, the platform is operable to dynamically calculate load-bearing capacities in real-time, as floor plans change in real-time.

In one embodiment, the platform is operable to automatically validate engineering assumptions for compliance with engineering safety standards. In one embodiment, the platform is operable to automatically validate structural load requirements, electrical system layout, electrical system load balancing, plumbing fixture placement, plumbing flow rates, HVAC system efficiency, and/or any other engineered assumptions.

In one embodiment, the platform is operable to optimize framing, joist spacing, and/or foundation loads based on materials and regional seismic/wind conditions. In one embodiment, the platform is operable to adapt engineering decisions based on regional building codes, soil conditions, and/or climate factors.

In one embodiment, the platform is operable to automatically generate fully engineered, construction-ready plans, wherein the construction-ready plans include foundation, framing, electrical, plumbing, and/or HVAC layouts. In one embodiment, the platform is operable to automatically perform structural, electrical, plumbing, and/or HVAC modeling. In one embodiment, the platform is operable to optimize piping, ductwork, and/or electrical runs based on the best routing paths determined by the platform.

In one embodiment, the platform is operable to generate predictions of future MEP performance issues, wherein the platform is operable to identify inefficiencies before construction begins.

In one embodiment, the platform is operable to automatically propose engineering solutions based on design modifications. In one embodiment, the platform is operable to optimize layouts for efficiency and/or cost savings.

In one embodiment, the platform is operable to identify conflicts between MEP systems and structural elements before permit submission, thereby providing real-time solutions to permitting issues, and adjusting construction project layouts to prevent costly on-site rework. In one embodiment, the platform is operable to automatically resolve clashes between ductwork, plumbing, and/or electrical pathways, thereby ensuring seamless coordination.

In one embodiment, the platform is operable to generate predictions of hidden structural and/or MEP elements within existing walls, wherein the platform is operable to utilize LiDAR scans and/or historical construction data to generate the predictions. In one embodiment, the platform is operable to generate inferences on the locations of framing, load-bearing walls, plumbing, and/or electrical wiring based on standard construction industry standards.

In one embodiment, the platform is operable to automatically suggest alternative framing materials and/or layouts based on cost savings and/or energy efficiency. In one embodiment, the platform is operable to optimize load paths and/or reinforcement strategies, thereby reducing unnecessary material use. In one embodiment, the platform is operable to provide automated energy efficiency reports, wherein the platform is further operable to provide recommendations for smarter MEP configurations based on the energy efficiency report.

### Procurement

In one embodiment, the platform is operable to automatically calculate the quantities of materials required for a construction project based on approved design, architecture, and/or engineering plans. In one embodiment, the materials include, but are not limited to, wood, concrete, plumbing, electrical materials, HVAC materials, and/or any other materials required for the construction project.

In one embodiment, the platform is operable to automatically provide real-time cost estimates of the required materials for the construction project, wherein the platform is operable to retrieve cost information from a plurality of supplier databases.

In one embodiment, the platform is operable to automatically suggest cost-effective materials, wherein the platform is operable to consider sustainability, availability, and/or construction project deadlines when generating suggestions. In one embodiment, the platform is operable to automatically adjust material suggestions based on real-time supply chain fluctuations and/or costs. In one embodiment, the platform is operable to cross-reference supplier inventories, wherein the platform is further operable to produce price comparisons and/or availability forecasts for supplies and materials required for a construction project.

In one embodiment, the platform is operable to automatically identify potential permit rejection risks based on selected material choices, the construction project scope, and/or zoning regulations. In one embodiment, the platform is operable to automatically suggest alternative materials and/or structural adjustments to improve permit approval success rates. In one embodiment, the platform is operable to continuously update material recommendations in real-time, in order to comply with evolving municipal codes and/or environmental regulations.

In an alternative embodiment, the platform is operable to integrate with procurement platforms to further facilitate the execution of construction projects.

### Permitting

In one embodiment, the platform is operable to automatically submit permits to the city for approval. In one embodiment, the platform is operable to automatically compile permit-ready plans based on the automated compliance, automated rendering, automated designing, and/or automated engineering, as previously described. In one embodiment, the platform is operable to automatically fill out the permit applications based on the construction project model and/or data.

In one embodiment, the platform is operable to convert 3D models into permit-standardized 2D CAD or PDF files, compatible for municipal review, thereby reducing manual errors and/or rework requirements by ensuring permit submittals meet all regulatory criteria upfront.

In one embodiment, the platform is operable to analyze historical permit rejection patterns, wherein the platform is further operable to identify high-risk design elements before submitting a permit application to a city. In one embodiment, the platform is operable to automatically predict permit rejection risks. In one embodiment, the platform is operable to automatically suggest corrections and/or modifications based on predicted permit rejection risks, to avoid permit delays.

In one embodiment, the platform is operable to automatically track municipal review feedback, wherein the platform is operable to learn from past submissions to the municipality and further refine permit applications automatically.

In one embodiment, the platform is operable to integrate with an API of a municipality. In one embodiment, the platform is operable to automatically direct submissions to a municipality via the API.

In one embodiment, the platform is operable to provide real-time permit tracking, including approval and/or rejection tracking. In one embodiment, the platform is operable to provide real-time status updates of the permit status. In one embodiment, the platform is operable to utilize conversational AI, wherein the platform is operable to automatically send and/or request status emails to an assigned municipal contact. In one embodiment, the platform is operable to automatically send a reminder to an assigned municipal contact. In one embodiment, the platform is operable to provide automated correspondence with an assigned municipal contact to ensure permit applications are not delayed in backlog.

In one embodiment, the platform is operable to automatically update the municipal contact information as municipal staffing and/or construction project assignments change.

### Inspection and Support

In one embodiment, the platform is operable to automatically compile and/or transfer all approved plans, engineering data, material selections, and/or permit documentation into a contractor-ready and/or vendor-ready package.

In one embodiment, the platform is operable to automatically generate a completed permit request/application, wherein the platform is operable to receive a user input including a signature on the permit request/application. In one embodiment, the platform is operable to automatically generate permit submissions to the applicable jurisdiction or entity. In another embodiment, the platform is operable to automatically generate permit submission follow-up communications to the applicable jurisdiction or entity.

In one embodiment, the platform is operable to integrate with construction management platforms, ensuring streamless synchronization of all construction project phases.

In one embodiment, the platform is operable to provide an AI-powered contractor onboarding assistant, wherein the contractor onboarding assistant is operable to provide automatic construction project summaries, scope-of-work breakdowns, and/or key compliance requirements.

In one embodiment, the platform is operable to dynamically assign construction project tasks based on pre-approved permit conditions.

In one embodiment, the platform is operable to continuously monitor a construction process in real time. In one embodiment, the platform is operable to integrate with job site imaging, drone scans, and/or digital field reports, wherein the platform is operable to automatically identify deviations from the approved construction plans. In one embodiment, the platform is operable to continuously monitor on-site changes, wherein if changes impact compliance, structural integrity, and/or permit conditions, the platform is operable to automatically identify and/or produce an alert based on the change. In one embodiment, the platform is operable to automate compliance re-routing by sending detected field modifications back through the systems of the platform, including, designing, engineering, and/or permitting for validation before execution. In one embodiment, the platform is operable to analyze proposed field modifications, wherein the platform is operable to provide predicted time, cost, and/or regulatory consequences of proposed field modifications.

In one embodiment, the platform is operable to provide predictive construction risk analysis and/or code compliance validation. In one embodiment, the platform is operable to predict whether a proposed field change will be permitted under municipal codes, before execution by the contractor and/or vendor. In one embodiment, the platform is operable to provide an inspection readiness analysis, wherein the platform verifies that all completed phases of the construction project comply with the approved plans before scheduling a municipal inspection of the construction project. In one embodiment, the platform is operable to provide dynamic compliance verification, wherein the platform is operable to automatically cross-reference the progress of the construction project against evolving city regulations. In one embodiment, the platform is operable to generate real-time quality assurance checklists, thereby reducing inspection failures and/or costly rework.

In one embodiment, the platform is operable to enable real-time digital twins of a construction site, wherein the digital twins are continuously updated with field modifications for accuracy.

### Project Status Tracking System

In an alternative embodiment, the platform includes a project status tracking system operable to track the step or phase of the project in real-time. In one embodiment, the project status tracking system includes a visualization of the project status. The project status tracking system is operable to track the project through discovery, designing, engineering, permitting, city submission, city review, and/or city approval.

In another embodiment, the platform is operable to receive project task inputs, wherein the platform is then operable to automatically assign the task input to a phase of the project, including, discovery, designing, engineering, permitting, city submission, city review, and/or city approval. For example, ‘soils report’ maps to the Discovery phase while ‘structural engineering’ maps to the Engineering phase.

In another embodiment, the platform is operable to automatically calculate dynamic timelines for a project and/or a phase of a project, wherein the platform is operable to automatically adjust phase completion dates based on factors such as accepted vendor bids. In one embodiment, the platform is operable to display progress of a project and/or a project phase as a percentage based on completed tasks versus total tasks.

### Vendor Bid Management

In one embodiment, the platform includes a multi-vendor bidding system wherein the system is operable to receive a proposal for a project from a vendor such as a contractor, wherein the system is operable to receive multiple proposals for the same project from a plurality of vendors, such as different contractors. Upon acceptance of a proposal, the platform is operable to automatically link the proposal to the project timeline, wherein the platform is operable to automatically adjust the corresponding phase completion date based on the vendor's committed delivery date in the proposal. In another embodiment, the platform is operable to track vendor payments, wherein payment tracking progresses through unpaid, partial, and paid states with recorded amounts and/or timestamps.

### User Application

In one embodiment, the platform is operable to be optimized for a user application via a server platform. In one embodiment, the server platform uses a system including at least one server computer and at least one user device. The at least one server computer is network-based or cloud-based. The at least one server computer includes at least one process and at least one memory. The at least one user device includes, but is not limited to, a desktop computer, a laptop computer, a smartphone, and/or a tablet. The at least one user device is operable to display a graphical user interface (GUI) for the server platform through a native web page, a downloaded software, and/or a mobile application. The GUI is preferable optimized for display in mobile and/or web formats.

### User Account

The server platform is operable to receive a request from at least one user device (e.g., a mobile phone, a computer, a tablet, etc.) to create an account and/or a user profile corresponding to one or more users. The server platform includes a plurality of accounts that are created upon registration with the server platform, with each account being linked to at least one user profile. Each of the at least one user profile includes account information identifying aspects of the user, user preferences, historical data for the user, and/or other data. Account information includes, but is not limited to, a name (e.g., first name, middle name, last name, nickname, username), a date of birth, a gender, an age, a race, an ethnicity, a physical address, a personal identification number (e.g., social security number (SSN), individual taxpayer identification number (ITIN)), at least one financial account (e.g., bank account number, credit card number, debit card number, digital wallet address, etc.), a job title, at least one email address, at least one phone number, a level of education, one or more additional authorized users with access to the account (e.g., a spouse, a child, etc.), and/or other user preferences. In one embodiment, the at least one user profile includes at least one designated means of contact for recovering account information (e.g., at least one email address, at least one phone number, at least one linked social media account, etc.).

In one embodiment, upon registration of a user profile and/or at a later time, the server platform receives answers to one or more challenge questions for a user profile. In one embodiment, the one or more challenge questions are selected from a preestablished list (e.g., What was your first pet?, What model was your first car?, etc.). In one embodiment, the server platform receives an input of a custom question and an answer for a user profile.

In one embodiment, the server platform prompts the user device to register one or more items of biometric information to associate with the user profile. In one embodiment, the biometric information includes one or more fingerprints, one or more retinal scans, one or more facial scans, and/or one or more voice samples (e.g., for voice pattern analysis). In one embodiment, upon registration of a user profile, the server platform prompts the user device to perform one or more typing tests in order to analyze a user's keystroke pattern. In one embodiment, in order to log in to the user profile, the server platform prompts a user to perform a typing test and compares the results to the user's keystroke pattern registered in association with the user profile. In another embodiment, the keystroke pattern is recognized as the username and/or password is entered to log into an account. Examples of keystroke recognition systems able to be utilized with the present invention include, but are not limited to, that described in U.S. Pat. No. 6,954,862. In one embodiment, at least one artificial intelligence module is used to detect and form a keystroke signature for each user and/or to recognize a user inputted keystroke pattern as matching the keystroke signature for a particular user profile.

### Log-In/Authentication

The server platform is able to receive a username and a password from a user device in order to login a user profile on the user device. In one embodiment, the server platform is able to receive a selection of “Forgot My Password” and receives a selection of one or more means of communication (e.g., at least one email address, at least one phone number). In one embodiment, the server platform automatically transmits a message to the one or more means of communication prompting to enter a new password. In another embodiment, the server platform automatically transmits a message to the one or more means of communication including the existing username and password information to allow the user to sign in.

In one embodiment, the server platform receives biometric information in order to log the user into the user profile. Biometric information includes, but is not limited to, retinal data, a facial image scan, one or more fingerprints, and/or voice pattern recognition. In one embodiment, biometric information includes a typing test to recognize a keystroke signature previously associated with the user profile.

In one embodiment, after successfully entering a username and password, the user device generates a challenge question GUI. In one embodiment, the server platform prompts for answers to one or more challenge questions associated with the at least one user profile. In another embodiment, the GUI on the user device includes a drop-down menu for a user profile to select one or more challenge questions and subsequently enter an answer matching a question and answer associated with the user profile. In one embodiment, the drop-down menu only includes questions previously associated with the user profile. In another embodiment, the drop-down menu includes questions having answers associated with the user profile as well as questions without answers associated with the user profile, forcing the user to know which questions have previously been addressed. In one embodiment, rather than being used as a subsequent step to enter a username and password, the challenge question GUI is required in order to authorize the server platform to send an account retrieval message to a designated account recovery communication means and/or to otherwise recover a username and password.

In one embodiment, the system includes an option for a user device to sign into a user profile via scanning at least one unique visual code. Examples of unique visual codes include bar codes, a quick response (QR) code, and/or any other form of visual code. After the user device scans the at least one unique visual code (e.g., via at least one camera and/or LiDAR sensor on the user device), the scan data is transmitted to the server platform. The server platform verifies the validity of the at least one unique visual code and/or matches the at least one unique visual code with the user profile. If the at least one unique visual code is successfully matched, then the user profile is logged in on the scanning user device.

In one embodiment, the system includes an option to log-in via at least one other device. In this system, when an attempt is made to log in on a first user device, the first user device automatically generates and displays a unique log-in code and a prompt to visit a log-in code page on a user device that is already signed into the user profile. Through the signed in user device (e.g., a mobile phone, a smart television, a computer, tablet, a smart watch, etc.), the server platform receives an input of the unique log-in code. Subsequently, the server platform automatically signs in the first user device to the user profile.

In one embodiment, in order to verify that the users logging in are legitimate users and not bots, the server platform generates at least one Completely Automated Public Turing test to tell Computers and Humans Apart (CAPTCHA). Upon the server platform receiving a selection that indicates a positive result for the at least one CAPTCHA, the user profile is successfully logged in.

In one embodiment, in order to login to a user profile, the user device transmits a login message to the server platform including location metadata. In one embodiment, the location metadata is generated by a Global Positioning System (GPS) chip found in the user device. In one embodiment, the server platform authenticates or rejects the login attempt based on the associated location metadata. By way of example and not limitation, if a user from one or more restricted countries (e.g., Argentina is restricted) attempts to login to a user profile, then the server platform automatically rejects the login attempt. In this embodiment, the server platform maintains a location blacklist, designating one or more locations from which login attempts will be rejected. However, in another embodiment, the server platform includes a location whitelist, designating a limited number of locations from which login attempts are able to be authenticated. This is particularly useful for security purposes and ensuring, by way of example and not limitation, that only login attempts made from a user's home are able to be accepted. In one embodiment, the whitelists and/or blacklists are global whitelists and/or blacklists that apply to all user profiles on the server platform. In another embodiment, the whitelists and/or blacklists are specific to each user profile, meaning locations are able to be restricted or allowed with respect to specific user profiles, but not with regard to other user profiles.

In one embodiment, the login page includes at least one button for logging in via other associated social media accounts (e.g., FACEBOOK, INSTAGRAM, LINKEDIN, GMAIL, YOUTUBE, REDDIT, X (formerly, TWITTER), MYSPACE, TUMBLR, MASTODON, etc.). The server platform receives a selection of one or more social media platforms from a user device and initiates an API call to verify that the user device being used to login is signed into an account on the selected one or more social media platforms on the user device. If no login using the associated social media account has previously been attempted, then the server platform automatically generates a user profile corresponding to the associated social media account. If an existing user profile exists corresponding to the associated social media account, then the server platform validates login into the existing user profile. This process is useful, as it allows a user to login and access the server platform without having to create a new username and password for the server platform. Furthermore, in one embodiment, the server platform is configured to automatically retrieve data corresponding to the associated social media account via at least API call to a database of the social media platform. In one embodiment, data retrieved via these means include bibliographical data (e.g., name, address, contact information, etc.) and/or preference data (e.g., estimated political views, estimated shopping preferences, estimated content preferences, etc.). In one embodiment, retrieved bibliographical data is used to automatically fill in information corresponding to the generated user profile on the server platform. In one embodiment, retrieved preference data is used to filter and select media displayed for the user profile on the server platform.

One of ordinary skill in the art will understand that one or more of the above-mentioned authentication methods are able to be used in order to log in a user device into a user profile. In one embodiment, the system utilizes multifactor authentication, transmitting an authentication message via one or more communication means (e.g., phone number, email address, one or more linked social media accounts, etc.) including a link to authenticate a login attempt and/or a code to enter in order to complete the login attempt.

### User Profile Page

In one embodiment, the server platform includes a profile page for each user profile. In one embodiment, the profile page includes a personal information regarding the user profile, including a name, an email address, a phone number, a location, an age, a gender, a race, an ethnicity, a religion, a sexual orientation, a current job title and/or one or more previous job titles, one or more educational degrees, at least one profile picture, at least one background wallpaper, and/or a calendar for the user profile.

### Construction Project Profile

In one embodiment, the server platform includes a construction project profile page for each construction project of a user. In one embodiment, the construction project profile page includes information regarding the construction project, including, a construction project name, a main project contact and contact information, other contacts, such as a contractor's name and contact information and/or vendor name(s) and contact information, a location, a parcel number, an existing structure description and/or photo (if applicable), a calendar and/or timeline for the construction project profile, photos and/or videos of the land, existing blueprints, scans, or other models of the structure and/or property, descriptions of the requested construction project, project budget, and/or any other information related to the construction project.

### Search Interface

In one embodiment, the server platform includes at least one search tool, wherein the at least one search tool receives one or more inputs (e.g., strings of characters) from a user device, automatically matches the one or more inputs with one or more data values in one or more databases and displays results corresponding to the matched data values. One of ordinary skill in the art will understand that the server platform is not limited as to the forms of search algorithm able to be used in the at least one search tool. Examples of search algorithms are to be used in the present invention include, but are not limited to, linear search algorithms, jump search algorithms, interpolation search algorithms, Fibonacci search algorithms, breadth-first search algorithms, lexicographic breadth-first search algorithms, depth-first search algorithms, iterative deepening depth-first search algorithms, brute-force search algorithms, binary search algorithms, beam search algorithms, stack search algorithms, difference-map algorithms, exponential search algorithms, golden-selection search algorithms, A* search algorithms, Lifelong Planning A* search algorithms, Iterative Deepening A* search algorithms, B* search algorithms, D* search algorithms (e.g., Focused D* search algorithms, D* Lite search algorithms, etc.), bidirectional search algorithms, Floyd-Warshall algorithm, fringe search algorithms, alpha-beta pruning, and/or any other search algorithm.

In one embodiment, the at least one search tool searches for data points based on values for one or more indices for each data point, categorizes the returned results by index, and displays the returned hits. By way of example and not limitation, if the at least one search tool receives the string “Hope,” the at least one search tool searches for people, groups, organizations, and/or other data objects in the one or more databases having the name “Hope” or “Hope” as a part of the name; people, groups, organizations and/or other data objects located at a place including the string “Hope;” posts made on the server platform including the string “Hope,” people, groups, organizations, posts, comments, and/or other data objects associated with a tag including the string “Hope;” and or any other index for any person, group, organization, post, comment, and/or other data object including the string “Hope.” These results are then categorized by index, showing, by way of example and not limitation, people having the name Hope, posts including the word “Hope,” places including the name “Hope,” restaurants including the string “Hope,” and/or other categories.

In one embodiment, the at least one search tool only returns results that include an exact match for the string, and results wherein the input string is delimited by spaces and/or by punctuation (and is therefore not part of a larger word). For example, searching the term “Hope” does not return the name “Hopewell.” In another embodiment, the at least one search tool returns all results including string and therefore does retrieve the name “Hopewell” with a search of “Hope.” In yet another embodiment, the at least one search tool returns known variations on the input search term, even where the results are not an exact string match, such as retrieving posts including the word “hoping” when the input string is “Hope.”

In one embodiment, the at least one search tool receives an input to search in one or more specific indices and/or categories of data objects. One example of the at least one search tool only searching for a specific index is limiting the search to only the name of a data object (e.g., the name of another user, the name of a places, the name of groups, the name of organizations, etc.), but only limiting the search to a specific index still allows the search to check that index shared by multiple categories of data objects (e.g., both users and organizations). However, in this example, the at least one search tool does not search for locations of users and/or organizations, posts made by users and/or organizations, and/or other indices. One example of the at least search tool only searching for a specific category is limiting the search to only organizations. However, limiting the search only by category still allows the at least one search tool to check multiple indices for that single category of data objects (e.g., names, locations, and posts for organizations). In one embodiment, the at least one search tool is able to be delimited by both index and category based on received limitation selections.

In one embodiment, the at least one search tool orders the list of returned search results based on one or more properties. In one embodiment, the order is based on date and/or time, such as the date and/or time a post was first made, a date and/or time a comment was first made, a date and/or time a user profile was first created, a date and/or time when a post or comment was most recently edited, and/or other similar properties. In one embodiment, the order begins with the oldest results. In another embodiment, the order begins with the newest results. In one embodiment, the at least one search tool orders the list of returned search results based on an alphabetical and/or alphanumerical sorting of the name or title of each returned data object and/or an alphabetical and/or alphanumerical sorting of one or more associated properties of each returned data object.

In one embodiment, the at least one search tool orders the list of returned search results based on a popularity score for each returned search result. In one embodiment, a popularity score is based on a total number of user profiles that have click-selected and/or opened each returned result, a total number of user profiles that have “liked” each returned result, a net number of user profiles that have liked each returned result minus a number of user profiles that have disliked each returned result, a number of specific user profiles that have click-selected.

In one embodiment, the at least one search tool returns search results in order of relevance, wherein order in a list of search results is based on a relevancy score generated by the server platform. In one embodiment, in order to prioritize and display the most relevant documents, the at least one search tool automatically weights one or more indices and/or one or more categories of data objects greater.

In one embodiment, the at least one search tool is capable of using traditional Boolean known to one of ordinary skill in the art.

In one embodiment, the at least one search tool receives, as an input, at least one image and/or image file in addition to or in lieu of a text string. The at least one search tool then queries at least one database and retrieves at least one similar or copy image and/or image file, an original artist for the audio and/or video file, an identity of who posted the image and/or image file, a time when the image and/or image was posted, a link to the image and/or image file, and/or other information regarding the image and/or image file. Examples of systems and methods for image search able to be used in the present application are described in patent documents including, but not limited to, U.S. Patent Pub. No. 2018/0276250 and U.S. Pat. Nos. 9,008,446, 9,053,115, 11,144,587, and/or 9,753,951. In another embodiment, the at least one search tool retrieves at least one image and/or at least one video based on a text string describing the at least one image and/or the at least one video using natural language processing, as described in patent applications including, but not limited to, U.S. Patent Pub. No. 2022/0075806.

In one embodiment, the at least one search tool receives, as an input, at least one audio file and/or video file in addition to or in lieu of a text string. The at least one search tool then queries at least one database and retrieves at least one similar or copy audio and/or video file, an original artist for the audio and/or video file, an identity of who posted the image and/or image file, a time when the image and/or image was posted, a link to the image and/or image file, and/or other information regarding the image and/or image file. Examples of system and methods for audio search able to be used in the present application are described in patent documents including, but not limited to, U.S. Patent Pub. No. 2014/0278845 and U.S. Pat. Nos. 8,688,248 and 9,390,170.

In one embodiment, the server platform includes at least one third-party search API, operable to access at least one third-party database. By way of example and not limitation, the server platform includes a GOOGLE and/or BING external search API.

### Construction Project Interface

In one embodiment, the server platform is operable to provide a visual project board. In one embodiment, the visual project board includes an interactive Kanban-style project board, wherein users can drag-and-drop tasks, create dependencies, and/or track real-time progress through the preconstruction progress of the construction project. In one embodiment, the server platform is operable to auto-update tasks based on real-time permit approvals, material procurement status, and/or engineering validations.

In one embodiment, the server platform is operable to provide task prioritization and/or auto-scheduling capabilities based on municipal review timelines, contractor availability, vendor availability, and/or material delivery dates.

In one embodiment, the server platform is operable to provide customizable workflow management of a construction project, wherein users can create tailored project stages that align with municipal approval processes, procurement schedules, and/or construction project milestones.

In one embodiment, the server platform is operable to provide intelligent team collaboration, wherein the server platform is operable to provide real-time collaboration between users, including comments, task assignments, mentions, and/or approval requests, thereby providing seamless coordination between homeowners, contractors, architects, vendors, and/or city reviewers. In one embodiment, the server platform is operable to provide automated notifications via SMS messages, emails, and/or in-app alerts. In one embodiment, the automated notifications are based on status changes, including, but not limited to, permit approval, material delivery, design feedback, engineering validation, and/or any other status change related to the construction project.

In one embodiment, the server platform is operable to provide white-labeling capabilities, wherein contractors, builders, vendors, and/or developers can rebrand the server platform under their own name, allowing seamless brand integration without requiring a new application deployment.

In one embodiment, the server platform is operable to provide permit and/or compliance tracking, as previously described herein. In one embodiment, the server platform is operable to provide status tracking of a construction project in real-time, including permit application progress, required modifications, and/or expected approval dates. In one embodiment, the server platform is operable to predict permit rejection risks based on historical city rejections, wherein the server platform is operable to provide suggested modifications before submission of a permit application based on the predicted permit rejection risk. In one embodiment, the server platform is operable to automatically submit resubmittals with recommended corrections.

In one embodiment, city reviewers are able to provide direct feedback through the server platform, wherein the server platform is operable to automatically translate the feedback into actionable next steps.

In one embodiment, the server platform is operable to automatically verify that the construction project remains compliant with zoning laws, environmental regulations, setback requirements, and/or any other compliance requirement as construction tasks progress. In one embodiment, the server platform is operable to produce an alert for a potential compliance issue and/or produce a suggestion for corrective actions before submission delays occur.

In one embodiment, the server platform is operable to automatically track material orders, delivery schedules, and/or pricing fluctuations based on supplier data, as previously described herein. In one embodiment, the server platform is operable to automatically suggest alternative vendors and/or materials if procurement delays are detected.

In one embodiment, the server platform is operable to provide a contractor and/or vendor management system, wherein the server platform is operable to provide status updates on construction phases in real-time. In one embodiment, the server platform is operable to automatically predict potential bottlenecks, wherein the server platform is further operable to recommend task reallocation based on a predicted potential bottleneck.

In one embodiment, the server platform is operable to integrate with external tools. In one embodiment, the external tools include, but are not limited to, GOOGLE DRIVE, DROPBOX, ONEDRIVE, MICROSOFT OUTLOOK, GMAIL, SLACK, MICROSOFT TEAMS, QUICKBOOKS, STRIPE, any other payment platform, and/or construction management platforms.

In one embodiment, the server platform is operable to automatically generate email and/or SMS message status updates for users.

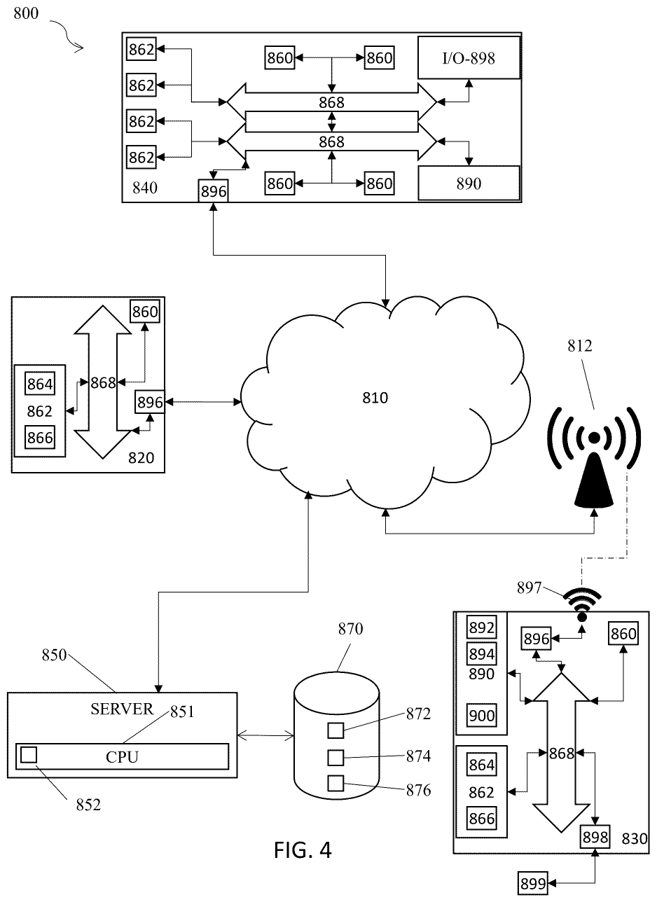

FIG. 4 is a schematic diagram of an embodiment of the invention illustrating a computer system, generally described as 800, having a network 810, a plurality of computing devices 820, 830, 840, a server 850, and a database 870.

The server 850 is constructed, configured, and coupled to enable communication over a network 810 with a plurality of computing devices 820, 830, 840. The server 850 includes a processing unit 851 with an operating system 852. The operating system 852 enables the server 850 to communicate through network 810 with the remote, distributed user devices. Database 870 is operable to house an operating system 872, memory 874, and programs 876.

In one embodiment of the invention, the system 800 includes a network 810 for distributed communication via a wireless communication antenna 812 and processing by at least one mobile communication computing device 830. Alternatively, wireless and wired communication and connectivity between devices and components described herein include wireless network communication such as WI-FI, WORLDWIDE INTEROPERABILITY FOR MICROWAVE ACCESS (WIMAX), Radio Frequency (RF) communication including RF identification (RFID), NEAR FIELD COMMUNICATION (NFC), BLUETOOTH including BLUETOOTH LOW ENERGY (BLE), ZIGBEE, Infrared (IR) communication, cellular communication, satellite communication, Universal Serial Bus (USB), Ethernet communications, communication via fiber-optic cables, coaxial cables, twisted pair cables, and/or any other type of wireless or wired communication. In another embodiment of the invention, the system 800 is a virtualized computing system capable of executing any or all aspects of software and/or application components presented herein on the computing devices 820, 830, 840. In certain aspects, the computer system 800 is operable to be implemented using hardware or a combination of software and hardware, either in a dedicated computing device, or integrated into another entity, or distributed across multiple entities or computing devices.

By way of example, and not limitation, the computing devices 820, 830, 840 are intended to represent various forms of electronic devices including at least a processor and a memory, such as a server, blade server, mainframe, mobile phone, personal digital assistant (PDA), smartphone, desktop computer, netbook computer, tablet computer, workstation, laptop, and other similar computing devices. The components shown here, their connections and relationships, and their functions, are meant to be exemplary only, and are not meant to limit implementations of the invention described and/or claimed in the present application.

In one embodiment, the computing device 820 includes components such as a processor 860, a system memory 862 having a random-access memory (RAM) 864 and a read-only memory (ROM) 866, and a system bus 868 that couples the memory 862 to the processor 860. In another embodiment, the computing device 830 is operable to additionally include components such as a storage device 890 for storing the operating system 892 and one or more application programs 894, a network interface unit 896, and/or an input/output controller 898. Each of the components is operable to be coupled to each other through at least one bus 868. The input/output controller 898 is operable to receive and process input from, or provide output to, a number of other devices 899, including, but not limited to, alphanumeric input devices, mice, electronic styluses, display units, touch screens, signal generation devices (e.g., speakers), or printers.

By way of example, and not limitation, the processor 860 is operable to be a general-purpose microprocessor (e.g., a central processing unit (CPU)), a graphics processing unit (GPU), a microcontroller, a Digital Signal Processor (DSP), an Application Specific Integrated Circuit (ASIC), a Field Programmable Gate Array (FPGA), a Programmable Logic Device (PLD), a controller, a state machine, gated or transistor logic, discrete hardware components, or any other suitable entity or combinations thereof that can perform calculations, process instructions for execution, and/or other manipulations of information.

In another implementation, shown as 840 in FIG. 4, multiple processors 860 and/or multiple buses 868 are operable to be used, as appropriate, along with multiple memories 862 of multiple types (e.g., a combination of a DSP and a microprocessor, a plurality of microprocessors, one or more microprocessors in conjunction with a DSP core).

Also, multiple computing devices are operable to be connected, with each device providing portions of the necessary operations (e.g., a server bank, a group of blade servers, or a multi-processor system). Alternatively, some steps or methods are operable to be performed by circuitry that is specific to a given function.

According to various embodiments, the computer system 800 is operable to operate in a networked environment using logical connections to local and/or remote computing devices 820, 830, 840 through a network 810. A computing device 830 is operable to connect to a network 810 through a network interface unit 896 connected to a bus 868. Computing devices are operable to communicate communication media through wired networks, direct-wired connections or wirelessly, such as acoustic, RF, or infrared, through an antenna 897 in communication with the network antenna 812 and the network interface unit 896, which are operable to include digital signal processing circuitry when necessary. The network interface unit 896 is operable to provide for communications under various modes or protocols.

In one or more exemplary aspects, the instructions are operable to be implemented in hardware, software, firmware, or any combinations thereof. A computer readable medium is operable to provide volatile or non-volatile storage for one or more sets of instructions, such as operating systems, data structures, program modules, applications, or other data embodying any one or more of the methodologies or functions described herein. The computer readable medium is operable to include the memory 862, the processor 860, and/or the storage media 890 and is operable to be a single medium or multiple media (e.g., a centralized or distributed computer system) that store the one or more sets of instructions 900. Non-transitory computer readable media includes all computer readable media, with the sole exception being a transitory, propagating signal per se. The instructions 900 are further operable to be transmitted or received over the network 810 via the network interface unit 896 as communication media, which is operable to include a modulated data signal such as a carrier wave or other transport mechanism and includes any delivery media. The term “modulated data signal” means a signal that has one or more of its characteristics changed or set in a manner as to encode information in the signal.

Storage devices 890 and memory 862 include, but are not limited to, volatile and non-volatile media such as cache, RAM, ROM, EPROM, EEPROM, FLASH memory, or other solid state memory technology; discs (e.g., digital versatile discs (DVD), HD-DVD, BLU-RAY, compact disc (CD), or CD-ROM) or other optical storage; magnetic cassettes, magnetic tape, magnetic disk storage, floppy disks, or other magnetic storage devices; or any other medium that can be used to store the computer readable instructions and which can be accessed by the computer system 800.

In one embodiment, the computer system 800 is within a cloud-based network. In one embodiment, the server 850 is a designated physical server for distributed computing devices 820, 830, and 840. In one embodiment, the server 850 is a cloud-based server platform. In one embodiment, the cloud-based server platform hosts serverless functions for distributed computing devices 820, 830, and 840.

In another embodiment, the computer system 800 is within an edge computing network. The server 850 is an edge server, and the database 870 is an edge database. The edge server 850 and the edge database 870 are part of an edge computing platform. In one embodiment, the edge server 850 and the edge database 870 are designated to distributed computing devices 820, 830, and 840. In one embodiment, the edge server 850 and the edge database 870 are not designated for distributed computing devices 820, 830, and 840. The distributed computing devices 820, 830, and 840 connect to an edge server in the edge computing network based on proximity, availability, latency, bandwidth, and/or other factors.

It is also contemplated that the computer system 800 is operable to not include all of the components shown in FIG. 4, is operable to include other components that are not explicitly shown in FIG. 4 or is operable to utilize an architecture completely different than that shown in FIG. 4. The various illustrative logical blocks, modules, elements, circuits, and algorithms described in connection with the embodiments disclosed herein are operable to be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application (e.g., arranged in a different order or partitioned in a different way), but such implementation decisions should not be interpreted as causing a departure from the scope of the present invention.

Certain modifications and improvements will occur to those skilled in the art upon a reading of the foregoing description. The above-mentioned examples are provided to serve the purpose of clarifying the aspects of the invention and it will be apparent to one skilled in the art that they do not serve to limit the scope of the invention. All modifications and improvements have been deleted herein for the sake of conciseness and readability but are properly within the scope of the present invention.

The invention claimed is:

1. A method for automated preconstruction management, comprising:
receiving, by a computer processor including a memory, a street address of a property;
conducting, by an artificial intelligence (AI) engine, analysis of the property by retrieving property data for the street address from at least one public record database;
retrieving, by the AI engine, assessor data for the street address from at least one additional public record database, wherein the assessor data includes at least one image of the property;
performing, by the AI engine, project scoping, wherein the AI engine receives at least one project input, wherein the AI engine is operable to generate at least one question based on the at least one project input;
receiving, by the AI engine, at least one natural language description, wherein the at least one natural language description includes at least one proposed change to the property;
creating, by the AI engine, a project for the property based on the at least one project input, wherein the project for the property includes predetermined parameters and the at least one proposed change on an interactive map;
generating, by the AI engine, at least one floor plan for the project based on the at least one natural language description;
displaying the interactive map via a graphical user interface (GUI) on at least one device;
searching at least one zoning database, by the AI engine, for at least one zoning rule for the street address;
conducting, by the AI engine, compliance validation analysis of the project by referencing the at least one zoning rule for the street address against the at least one proposed change to the property;
automatically adjusting, by the AI engine, the at least one floor plan for the project based on the compliance validation analysis; and
submitting, by the AI engine, at least one permit application to a municipality for approval.

2. The method of claim 1, wherein the property data includes an assessor parcel number (APN), a lot size, a zoning designation, property boundary coordinates, an existing building square footage, a year of build, financial data, and/or ownership information.

3. The method of claim 1, wherein the at least one zoning rule includes a setback requirement, a maximum lot coverage, a maximum building height, a maximum number of building stories, and/or an accessory dwelling unit (ADU) regulation.

4. The method of claim 1, wherein the at least one question is related to a project type, an approximate square footage, a structural change, a plumbing change, and/or an electrical panel upgrade.

5. The method of claim 1, wherein the predetermined parameters include property boundaries, setback lines, existing structure footprints, buildable area, and/or lot coverage.

6. The method of claim 1, further comprising calculating, by the AI engine, types and quantities of materials required for the project based on the at least one proposed change.

7. The method of claim 1, further comprising monitoring, by the AI engine, project progress in real time and further comprising automatically adjusting, by the AI engine, a project timeline based on the monitored project progress.

8. The method of claim 1, further comprising receiving at least one proposal from at least one project vendor.

9. The method of claim 1, further comprising saving, by the AI engine, the analysis in at least one database.

10. A system for automated preconstruction management, comprising:
a server platform with a processor including a memory and the server platform includes at least one artificial intelligence (AI) engine;
wherein the at least one processor is operable to receive a street address of a property;
wherein the AI engine is operable to conduct analysis of the property by retrieving property data for the street address from at least one public record database;
wherein the AI engine is operable to retrieve assessor data for the street address from at least one additional public record database, wherein the assessor data includes at least one image of the property;
wherein the AI engine is operable to perform project scoping, wherein the AI engine is operable to receive at least one project input, wherein the AI engine is operable to generate at least one question based on the at least one project input;
wherein the AI engine is operable to receive at least one natural language description, wherein the at least one natural language description includes at least one proposed change to the property;
wherein the AI engine is operable to create a project for the property based on the at least one project input, wherein the project for the property includes predetermined parameters and the at least one proposed change on an interactive map;
wherein the AI engine is operable to generate at least one floor plan for the project based on the at least one natural language description;
wherein the interactive map is displayed via a graphical user interface (GUI) on at least one user device;
wherein the AI engine is operable to search at least one zoning database for at least one zoning rule for the street address;
wherein the AI engine is operable to conduct compliance validation analysis of the project by referencing the at least one zoning rule for the street address against the at least one proposed change to the property;
wherein the AI engine is operable to automatically adjust the at least one floor plan for the project based on the compliance validation analysis; and
wherein the AI engine is operable to submit at least one permit application to a municipality for approval.

11. The system of claim 10, wherein the property data includes an assessor parcel number (APN), a lot size, a zoning designation, property boundary coordinates, an existing building square footage, a year of build, financial data, and/or ownership information.

12. The system of claim 10, wherein the at least one zoning rule includes a setback requirement, a maximum lot coverage, a maximum building height, a maximum number of building stories, and/or an accessory dwelling unit (ADU) regulation.

13. The system of claim 10, wherein the predetermined parameters include property boundaries, setback lines, existing structure footprints, buildable area, and/or lot coverage.

14. The system of claim 10, wherein the system is operable to receive at least one proposal from at least one project vendor.

15. The system of claim 10, wherein the AI engine is operable to monitor project progress in real time, wherein the AI engine is further operable to automatically adjust a project timeline based on monitored project progress.

16. A method for automated preconstruction management, comprising:
receiving, by a computer processor including a memory, a street address of a property;
conducting, by an artificial intelligence (AI) engine, analysis of the property by retrieving property data for the street address from at least one public record database;
retrieving, by the AI engine, assessor data for the street address from at least one additional public record database, wherein the assessor data includes at least one image of the property;
performing, by the AI engine, project scoping, wherein the AI engine receives at least one project input, wherein the AI engine is operable to generate at least one question based on the at least one project input;
receiving, by the AI engine, at least one natural language description, wherein the at least one natural language description includes at least one proposed change to the property;
creating, by the AI engine, a project for the property based on the at least one project input, wherein the project for the property includes predetermined parameters and the at least one proposed change on an interactive map;
generating, by the AI engine, at least one floor plan for the project based on the at least one natural language description;
displaying the interactive map via a graphical user interface (GUI) on at least one device;
searching at least one zoning database, by the AI engine, for at least one zoning rule for the street address;
conducting, by the AI engine, compliance validation analysis of the project by referencing the at least one zoning rule for the street address against the at least one proposed change to the property;
automatically adjusting, by the AI engine, the at least one floor plan for the project based on the compliance validation analysis;
submitting, by the AI engine, at least one permit application to a municipality for approval;
monitoring, by the AI engine, project progress in real time; and
automatically adjusting, by the AI engine, a project timeline based on the monitored project progress.

17. The method of claim 16, wherein the property data includes an assessor parcel number (APN), a lot size, a zoning designation, property boundary coordinates, an existing building square footage, a year of build, financial data, and/or ownership information.

18. The method of claim 16, wherein the at least one zoning rule includes a setback requirement, a maximum lot coverage, a maximum building height, a maximum number of building stories, and/or an accessory dwelling unit (ADU) regulation.

19. The method of claim 16, wherein the predetermined parameters include property boundaries, setback lines, existing structure footprints, buildable area, and/or lot coverage.

20. The method of claim 16, further comprising calculating, by the AI engine, types and quantities of materials required for the project based on the at least one proposed change.
